(19) United States
(12) Patent Application Publication
(10) Pub. No.: US 2026/0047209 A1
(43) Pub. Date: Feb. 12, 2026

(54) BACKSIDE DEVICES

(71) Applicant: Taiwan Semiconductor Manufacturing Company, Ltd., Hsinchu (TW)

(72) Inventors: Hung-Li Chiang, Taipei City (TW); Jer-Fu Wang, Taipei City (TW); Carlo Gilardi, Hsinchu (TW); Iuliana Radu, Zhubei City (TW)

(21) Appl. No.: 18/799,774

(22) Filed: Aug. 9, 2024

(51) Int. Cl. H01L 27/06; H01L 21/265; H01L 21/822; H01L 23/528; H01L 29/06; H01L 29/423; H01L 29/49; H01L 29/66; H01L 29/775; H01L 29/786; H10B 80/00

(52) U.S. Cl. CPC H10D 88/101; H01L 21/265; H01L 23/528; H10D 84/038; H10D 88/01; H10B 80/00; H10D 30/014; H10D 30/43; H10D 30/6735; H10D 30/6757; H10D 62/121; H10D 64/663; H10D 64/668

(57) ABSTRACT

Device structures and methods of forming the same are provided. A device structure according to the present disclosure includes a substrate having a front side and a back side, a fin structure over the front side, a plurality of nanostructures disposed over the fin structure, a gate structure wrapping around each of the plurality of nanostructures, a first doped region disposed over the back side of the substrate, a backside dielectric layer over the first doped region, and a first contact feature extending through the backside dielectric layer to interface the first doped region.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

The shrinkage in device dimensions presents stress on electrical routing and placement of components in the back-end-of-line (BEOL) structures. In some applications, larger active or passive components may be placed in certain layers of a frontside interconnect structure. This practice meets several challenges. For example, these active or passive components may take up precious real estate in the frontside interconnect structure, which may lead to difficulties in satisfying footprint or design requirements. For another example, electrical signal to and from these passive or active components may need to go through more than one metallization layers, which may lead to undesirable increase in resistance and capacitance.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of method 100 for forming a semiconductor device, according to one or more aspects of the present disclosure.

FIGS. 2-20 illustrate fragmentary cross-sectional views of a work-in-progress (WIP) structure during a fabrication process according to the method of FIG. 1, according to one or more aspects of the present disclosure.

FIG. 21 illustrates a flowchart of method 400 for forming a semiconductor device, according to one or more aspects of the present disclosure.

FIGS. 22-44 illustrate fragmentary cross-sectional views of a work-in-progress (WIP) structure during a fabrication process according to the method of FIG. 21, according to one or more aspects of the present disclosure.

FIG. 45 schematically illustrates a cross-sectional view of a device die that includes first-type through substrate vias, according to one or more aspects of the present disclosure.

FIG. 46 schematically illustrates a cross-sectional view of a device that includes second-type through substrate vias, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Semiconductor fabrication generally includes front-end-of-line (FEOL) and back-end-of-line (BEOL) processes. The FEOL processes include steps to form individual components on a semiconductor substrate. The BEOL processes include steps to form interconnect structures to interconnect individual components formed by the FEOL processes. As integrated circuit (IC) technologies progress towards smaller technology nodes, multi-gate metal-oxide-semiconductor field effect transistor (multi-gate MOSFET, or multi-gate devices) have been widely adopted at the FEOL level to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor.

Besides multi-gate devices, many circuit applications include bipolar junction transistors (BJTs), diodes, resistors, capacitors, planar devices, or embedded dynamic random access memory (eDRAM) devices that are not compatible with manufacturing processes for multi-gate devices or cannot be satisfactorily replaced with multi-gate devices. Because bipolar junction transistors (BJTs), diodes, resistors, capacitors, or planar devices have much greater dimensions, they are often fabricated at the BEOL level in metal layers farther away from the FEOL structures. The increased distance requires additional metal routing in the interconnect structures and additional parasitic resistance and parasitic capacitance. In some practices, eDRAMs are implemented using multi-gate devices fabricated at the FEOL level. While being a viable solution, eDRAM implemented using multi-gate devices may not have satisfactory memory retention and requires frequent refreshing.

The present disclosure provides methods and structures to implement passive and active components on a back side of a substrate while FEOL devices are fabricated on a front side of the substrate. In terms of processes, selective deep ion-implantation processes are used to form an ion implantation profile in a substrate before multi-gate devices are fabricated. After the multi-gate devices and a frontside interconnect structure are fabricated over a front side of the substrate, the substrate is flipped up-side down and backside devices are formed over or around the ion implantation profile. The backside devices may include diodes, bipolar junction transistors (BJTs), resistors, capacitors, planar transistors, or embedded DRAMs. Implementation of the components on the back side of the substrate provides a relaxed footprint, which improves performance and reliability. The backside components may also reduce parasitic resistance, reduce parasitic capacitance, improve energy efficiency and performance, or improve memory retention.

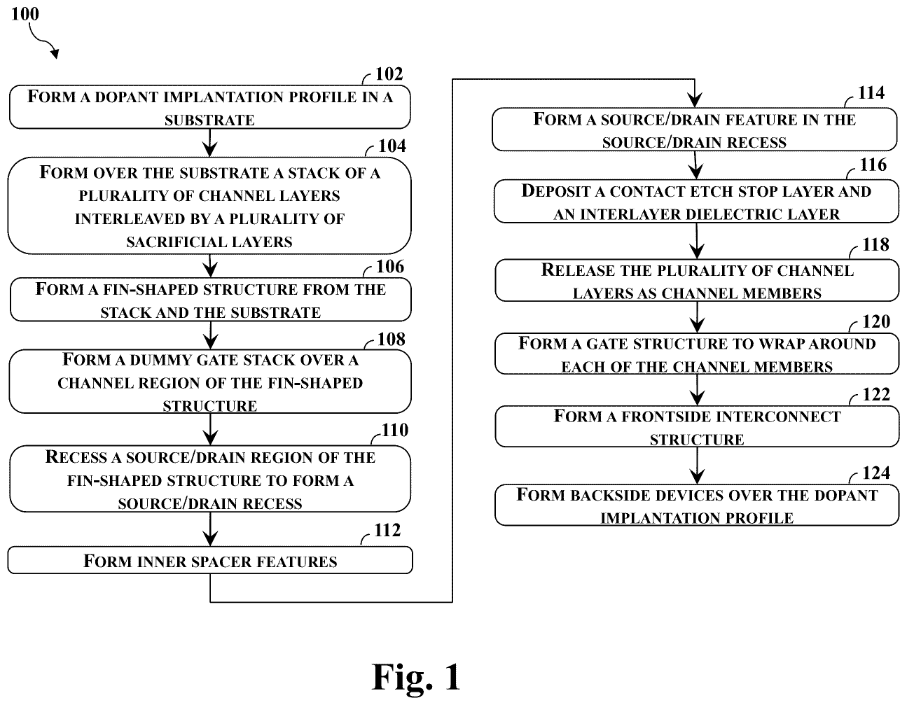

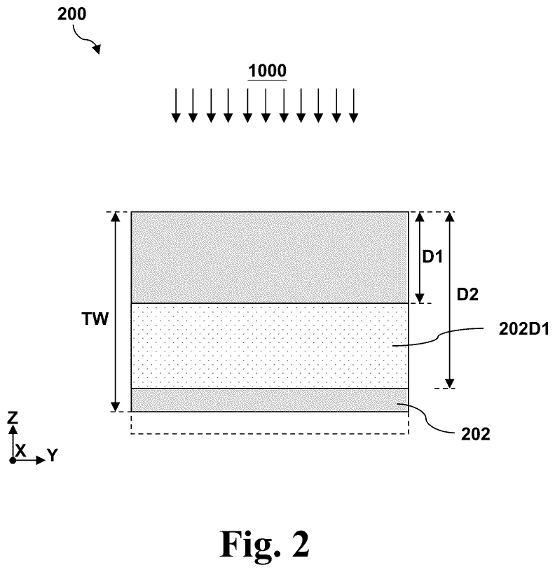

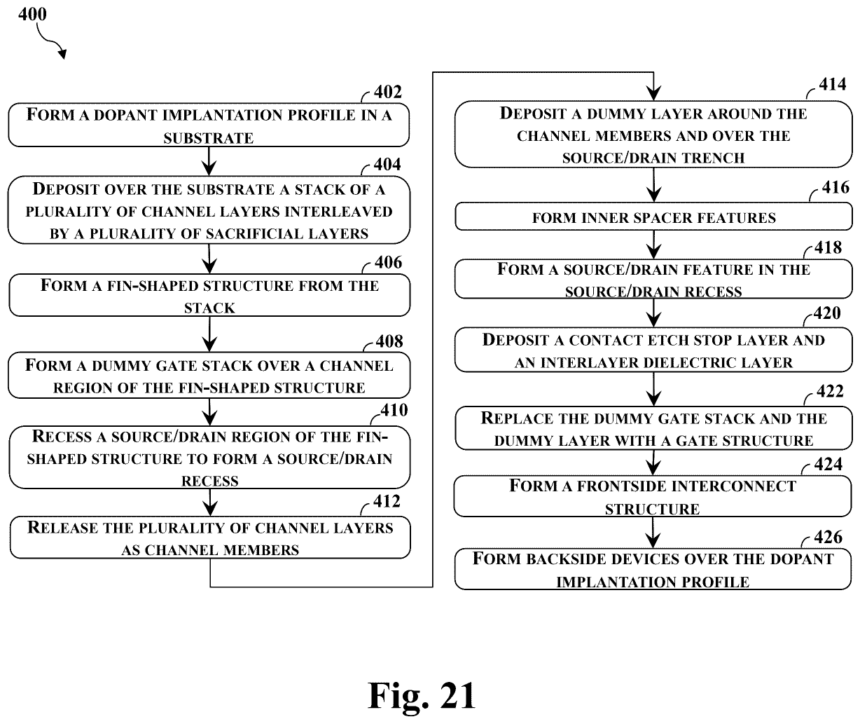

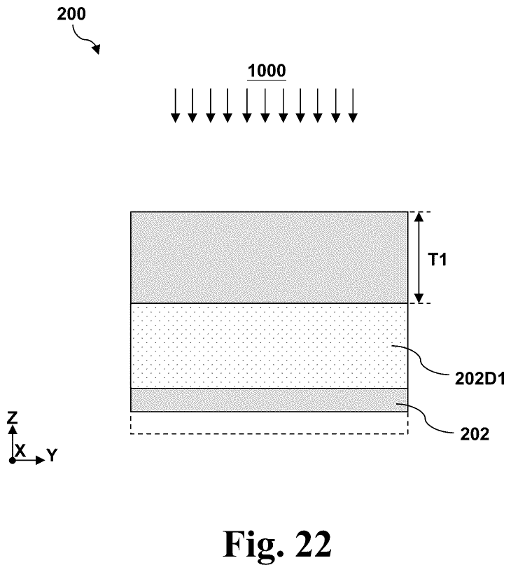

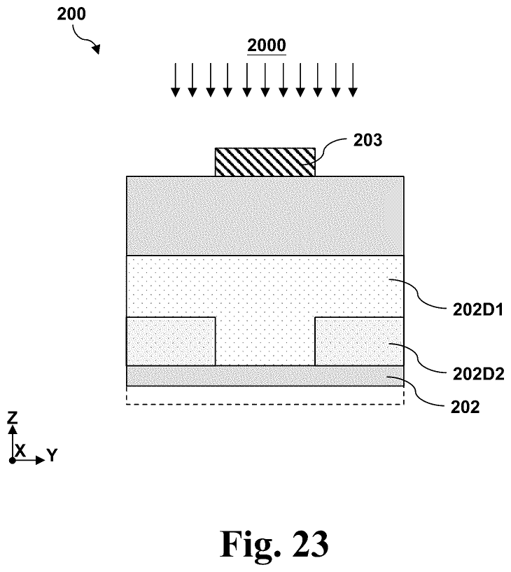

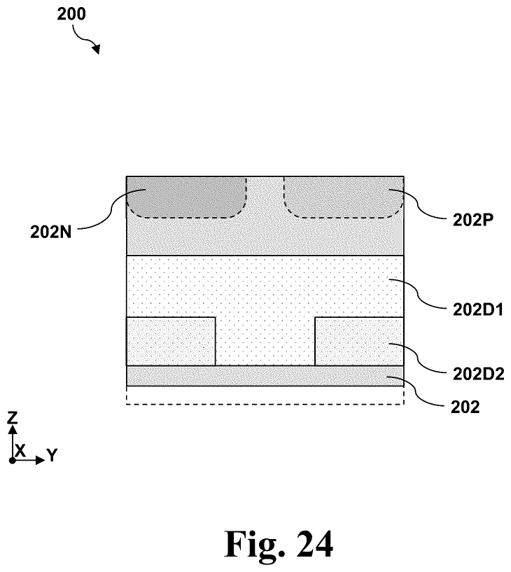

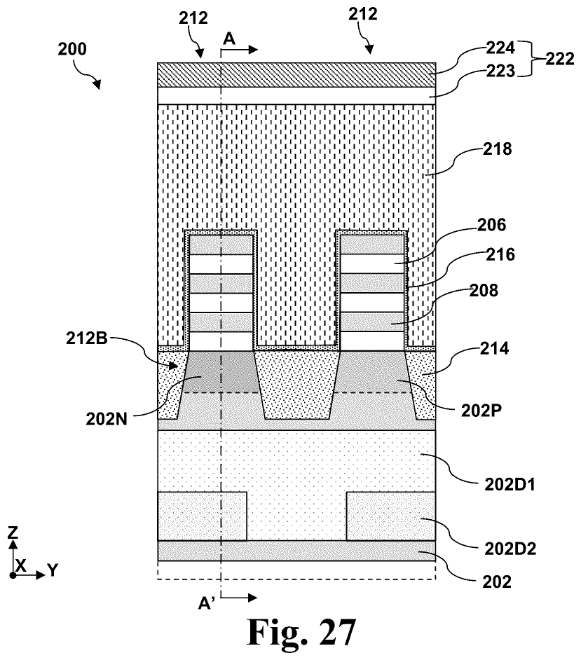

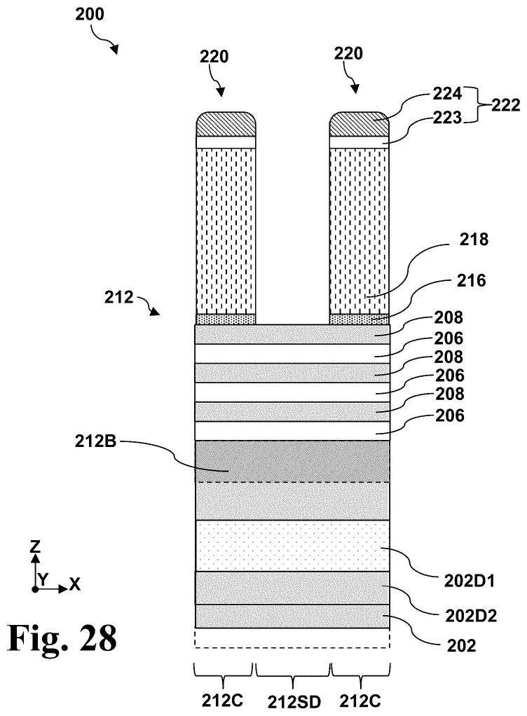

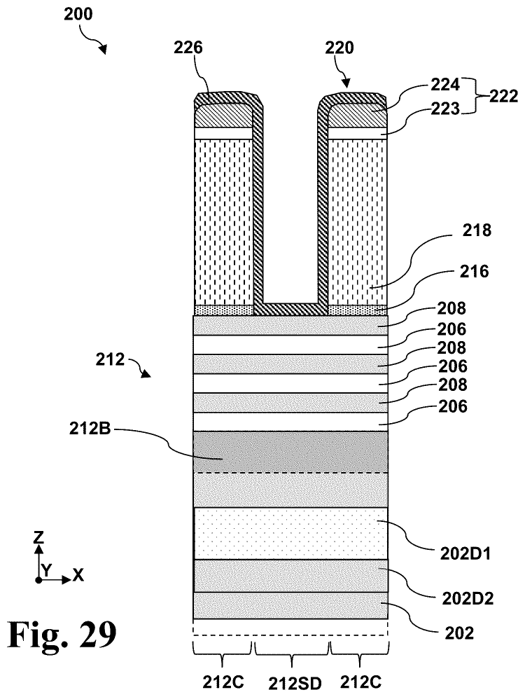

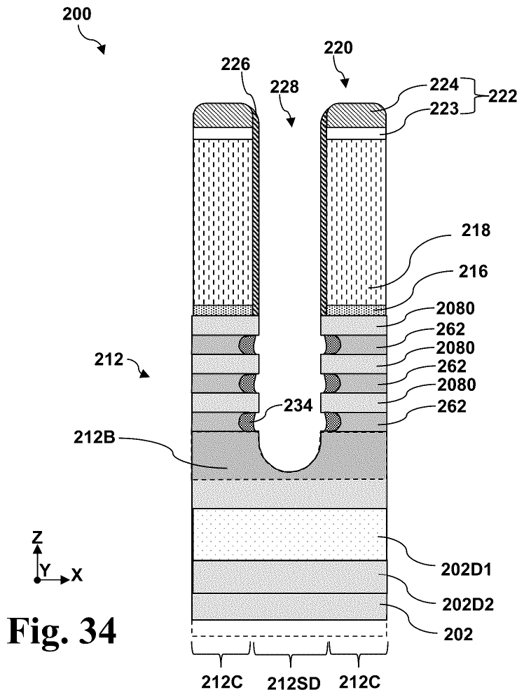

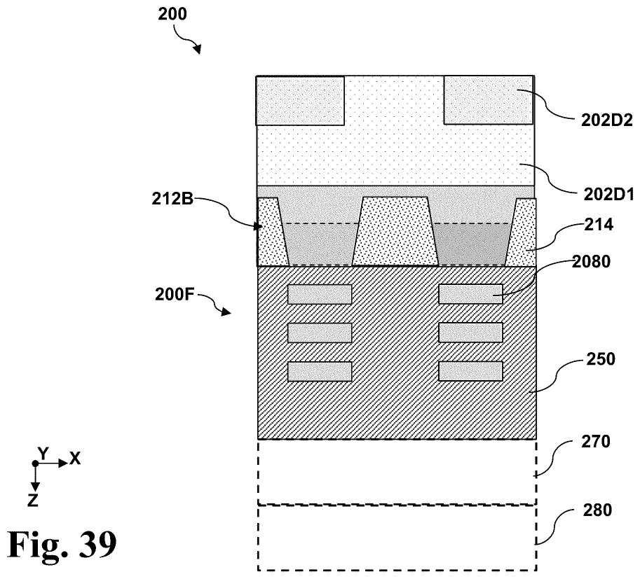

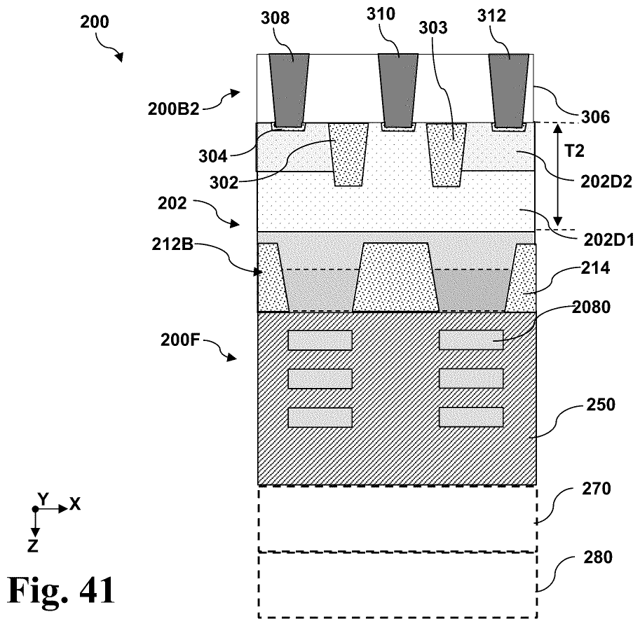

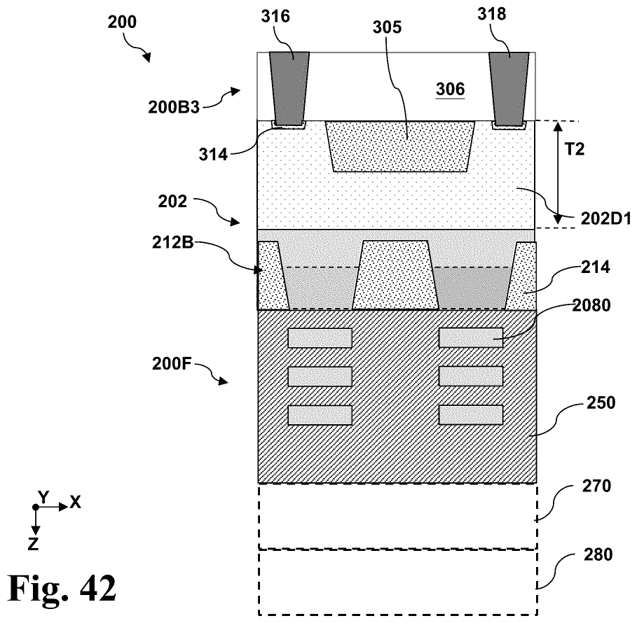

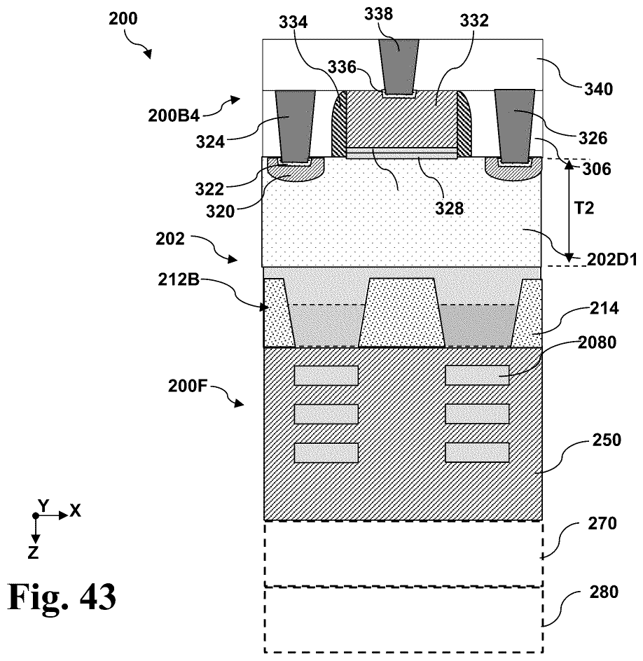

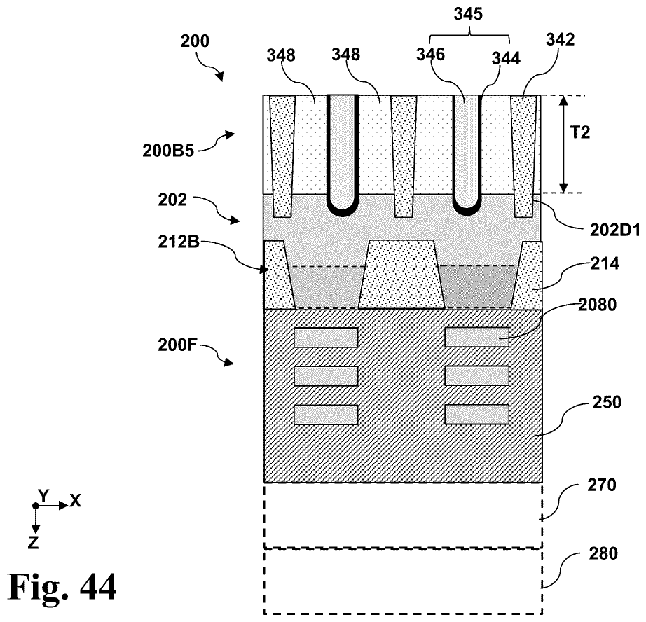

The various aspects of the present disclosure will now be described in more detail with reference to the figures. In that regard, FIG. 1 and FIG. 21 are flowcharts illustrating method 100 and method 400 of forming a semiconductor structure from a work-in-progress (WIP) structure according to embodiments of the present disclosure. Method 100 and 400 are merely examples and are not intended to limit the present disclosure to what is explicitly illustrated in method 100 and method 400. Additional steps can be provided before, during and after method 100 or method 400, and some steps described can be replaced, eliminated, or moved around for additional embodiments of the method. Not all steps are described herein in detail for reasons of simplicity. Method 100 is described below in conjunction with FIG. 2-20, which are fragmentary cross-sectional views of a WIP structure 200 at different stages of fabrication according to embodiments of the method 100 in FIG. 1. Method 400 is described below in conjunction with FIG. 22-44, which are fragmentary cross-sectional views of a WIP structure 200 at different stages of fabrication according to embodiments of the method 300 in FIG. 21. Because the WIP structure 200 will be fabricated into a semiconductor structure or a semiconductor device, the WIP structure 200 may be referred to herein as a semiconductor structure 200 or a semiconductor device 200 as the context requires. For avoidance of doubts, the X, Y and Z directions in FIGS. 2-20 and 22-44 are perpendicular to one another. Throughout the present disclosure, unless expressly described otherwise, like reference numerals denote like features or steps.

Method 100 and method 400 both include steps of forming GAA transistors. Both method 100 and method 400 start out by forming a dopant implantation profile in a substrate and forming a stack over the substrate, where the stack includes a plurality of channel layers interleaved by a plurality of sacrificial layers. After the GAA transistors are formed, both methods 100 and 400 include steps to form various backside devices. With respect to formation of the GAA transistors, method 100 and method 400 include steps to pattern the stack to form fin-shaped structures. Method 100 keeps the sacrificial layers in channel regions of the fin-shaped structures until after formation of source/drain features in source/drain regions of the fin-shaped structures. Different from method 100, method 400 removes the sacrificial layers after formation of dummy gate stacks and deposits a dummy layer to interleave the channel layers. The dummy layer is removed after formation of source/drain features in the source/drain regions of the fin-shaped structures. Method 100 and method 400 will be described below. Detailed descriptions of similar operations may be omitted for brevity. Like references referred to in conjunction with descriptions of method 100 and method 400 should be deemed interchangeable unless otherwise expressly described in the present disclosure. Attention is first directed to method 100 in FIG. 1.

Referring to FIGS. 1 and 2-4, method 100 includes a block 102 where a dopant implantation profile is formed in a substrate 202. The dopant implantation profile formed at block 102 is configured based on types and designs of the backside device to be formed using method 100. In the depicted embodiments, the dopant implantation profile includes a first-type dopant region 202D1 and a second-type dopant region 202D2 selectively formed in the first-type dopant implantation profile. In some embodiments, the first-type dopant region 202D1 may include p-type dopants and the second-type dopant region 202D2 may include n-type dopants. In some alternative embodiments, the first-type dopant region 202D1 may include n-type dopants and the second-type dopant region 202D2 may include p-type dopants. When the backside device is a planar device, a resistor, or a capacitor, the dopant implantation profile formed at block 102 may include a single region with the same conductivity type. When the backside device is a bipolar junction transistor or a diode, the dopant implantation profile formed at block 102 may include dopants of two different conductivity types. Operations at block 102 will be described in more detail below using an example where the dopant implantation profile includes regions of different conductivity types.

Reference is first made to FIG. 2, which illustrates a substrate 202. The substrate 202 may be a semiconductor substrate such as a silicon (Si) substrate. The substrate 202 may also include other semiconductors such as germanium (Ge), silicon carbide (SiC), silicon germanium (SiGe), germanium tin (GeSn), or diamond. In one embodiment, the substrate 202 is a silicon (Si) substrate. In some embodiments represented in FIG. 2, a deep well ion implantation process 1000 is performed to create a first-type dopant region 202D1 in the substrate 202. The deep well ion implantation process 1000 is configured to form the first-type dopant region 202D1 at a first depth D1. The first-type dopant region 202D1 is designed to reach to second depth D2. In some embodiments, the first depth D1 may be between about 50 nm and about 100 nm and the second depth D2 may be between about 100 nm and about 300 nm. The first depth D1 represents an area where method 100 forms the FEOL multi-gate devices. In some instances, the deep well ion implantation process 1000 includes an ion energy between 50 keV and about 1000 keV and an ion dosage between about 1×10¹¹ atoms/cm² and about 1×10¹³ atoms/cm². In embodiments where the substrate 202 is a 300 mm silicon wafer, the substrate 202 may have a wafer thickness Tw between about 750 μm and about 800 μm. For case of illustration, a majority of the wafer thickness TW is represented by the dotted line. As will be described further below, before backside devices are formed over the ion implantation profile, a majority of the substrate 202 may be ground or polished away to expose the first-type dopant region 202D1. The deep well ion implantation process 1000 may implant n-type dopant (e.g., phosphorus (P) or arsenic (As)) or p-type dopant (e.g., boron (B)).

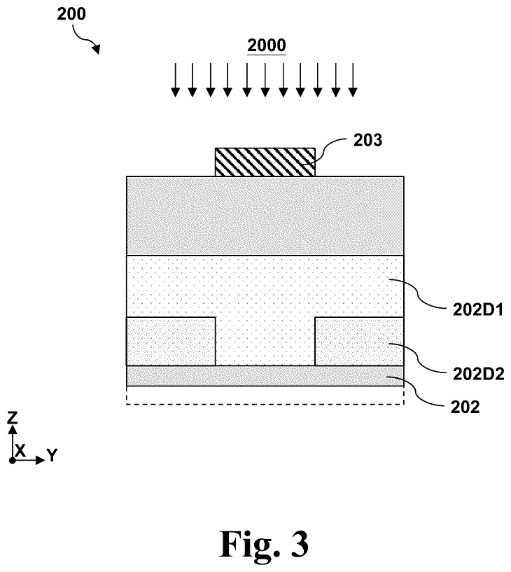

Reference is now made to FIG. 3. In embodiments where the backside devices require implantation regions of different conductivity types, a selective deep well ion implantation process 2000 is performed. Different from the deep well ion implantation process 1000, the selective deep well ion implantation process 2000 includes use of an ion implantation mask 203, which may include a photoresist, silicon oxide, or a combination thereof. Additionally, ion energy of the selective deep well ion implantation process 2000 may be greater than that of the deep well ion implantation process 1000. In some instances, the ion energy of the selective deep well ion implantation process 2000 may be between about 80 keV and about 1200 keV. The greater ion energy of the selective deep well ion implantation process 2000 allows formation of a second-type dopant region 202D2 that has a greater depth than the first-type dopant region 202D1. Like the deep well ion implantation process 1000, the selective deep well ion implantation process 2000 may implant n-type dopant (e.g., phosphorus (P) or arsenic (As)) or p-type dopant (e.g., boron (B)), as long as the first-type dopant region 202D1 and the second-type dopant region 202D2 have different conductivity types. The first-type dopant region 202D1, the second-type dopant region 202D2, or other dopant region combinations may be referred to as a dopant implantation profile. After the selective deep well ion implantation process 2000, the ion implantation mask 203 is removed.

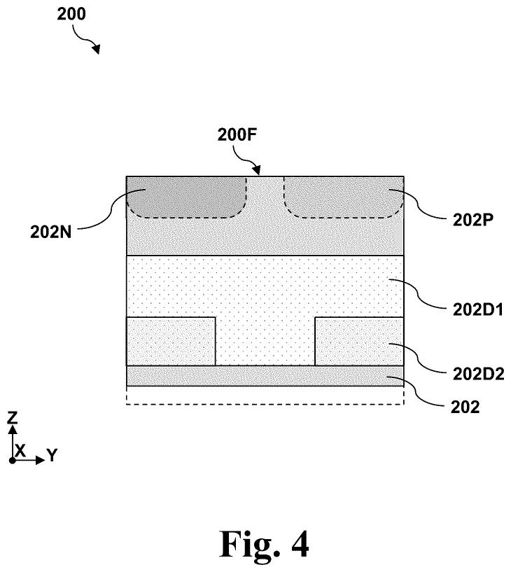

Referring to FIG. 4, n-wells 202N and p-wells 202P may be optionally formed near a front side surface 200F of the substrate 202 as counter-doped regions to reduce leakage. In some embodiments, formation of the n-wells 202N and p-wells 202P may be omitted as most of the substrate 202 is ground away. Different from the first-type dopant region 202D1 and the second-type dopant region 202D2, n-wells 202N and p-wells 202P are formed using low energy ion implantation process that implements an ion energy less than 10 keV. In an example process, a first masking layer that exposes the to-be n-well regions is formed and n-type dopant is implanted in the to-be n-well regions. The first masking layer is removed and a second masking layer is formed to cover the n-wells 202N while the p-wells 202P are formed by low energy ion implantation. Alternatively, the p-well regions may be formed first. It is noted that the concentration, pattern and depth of the first-type dopant region 202D1 and the second-type dopant region 202D2 are configured and selected for the purposes of forming the backside devices. The first-type dopant region 202D1 and the second-type dopant region 202D2 are not formed to serve as a leakage prevention measure of the multi-gate device to be formed at blocks 104 to 120. Similarly, the n-wells 202N and p-wells 202P are formed to serve design needs of the multi-gate devices and do not serve as a leakage prevention measure of the backside devices.

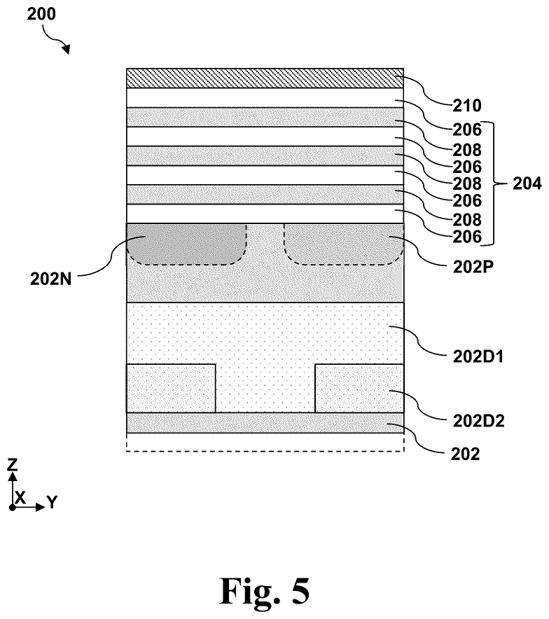

Referring to FIGS. 1 and 5, method 100 includes a block 104 where a stack 204 of alternating semiconductor layers is formed over the 202. In some embodiments, the stack 204 includes channel layers 208 of a first semiconductor composition interleaved by sacrificial layers 206 of a second semiconductor composition. It can also be said that the sacrificial layers 206 are interleaved by the channel layers 208. The first and second semiconductor compositions may be different. In some embodiments, the sacrificial layers 206 include silicon germanium (SiGe) or germanium tin (GeSn) and the channel layers 208 include silicon (Si). It is noted that four (4) layers of the sacrificial layers 206 and three (3) layers of the channel layers 208 are alternately arranged as illustrated in FIG. 5, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 includes an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

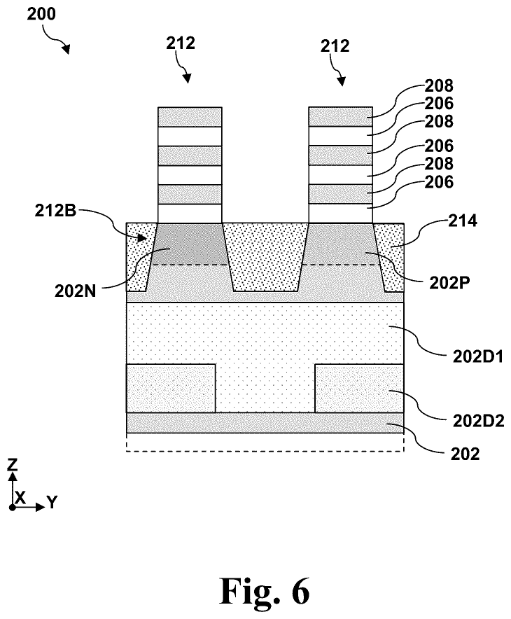

Referring to FIGS. 1 and 6, method 100 includes a block 106 where a fin-shaped structure 212 is formed from the stack 204 and the substrate 202. To pattern the stack 204, a hard mask layer 210 (shown in FIG. 5) may be deposited over the stack 204 to form an etch mask. The hard mask layer 210 may be a single layer or a multi-layer. For example, the hard mask layer 210 may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 6, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 6, the fin-shaped structure 212 that includes the sacrificial layers 206 and the channel layers 208 extends vertically along the Z direction and lengthwise along the X direction. As shown in FIG. 6, the fin-shaped structure 212 includes a base fin structure 212B patterned from the substrate 202. The patterned stack 204, including the sacrificial layers 206 and the channel layers 208, is disposed directly over the base fin structure 212B.

At block 106, an isolation feature 214 is formed adjacent to the fin-shaped structure 212. In some embodiments represented in FIG. 6, the isolation feature 214 is disposed on sidewalls of the base fin structure 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 6. The fin-shaped structure 212 rises above the STI feature 214 after the recessing, while the base fin structure 212B is embedded or buried in the isolation feature 214.

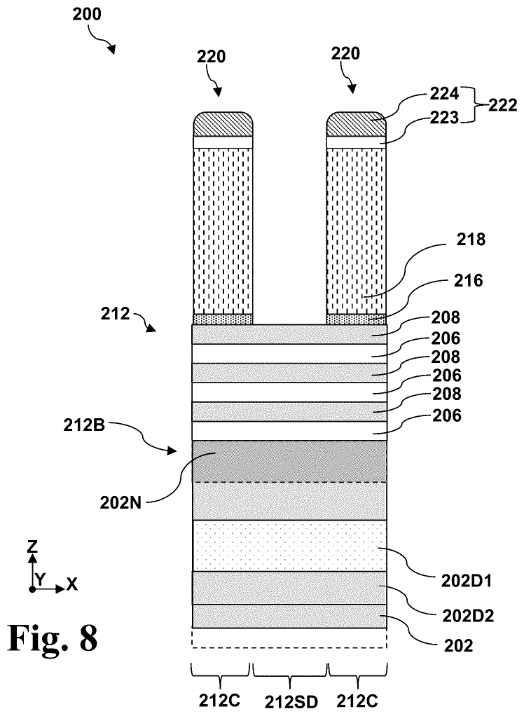

Referring to FIGS. 1 and 7-9, method 100 includes a block 108 where a dummy gate stack 220 is formed over a channel region 212C of the fin-shaped structure 212. In some embodiments, a gate replacement process (or gate-last process) is adopted where the dummy gate stack 220 serves as a placeholder to undergo various processes and is to be removed and replaced by a functional gate structure. Other processes and configuration are possible. In some embodiments illustrated in FIG. 8, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 8, the channel region 212C is disposed between two source/drain regions 212SD along the X direction.

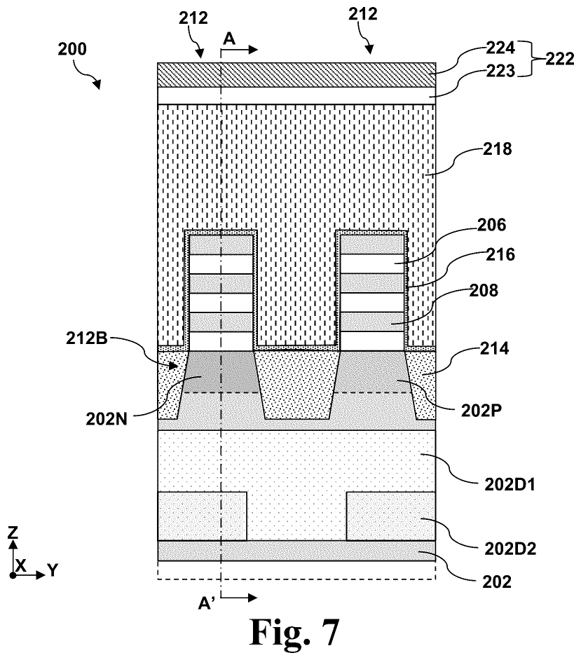

The formation of the dummy gate stack 220 may include deposition of layers in the dummy gate stack 220 and patterning of these layers. Referring to FIG. 7, a dummy dielectric layer 216, a dummy electrode layer 218, and a gate-top hard mask layer 222 may be blanketly deposited over the WIP structure 200. In some embodiments, the dummy dielectric layer 216 may be formed on the fin-shaped structure 212 using a chemical vapor deposition (CVD) process, an ALD process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 8. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 8, the dummy gate stack 220 is patterned such that it is only disposed over the channel region 212C, not disposed over the source/drain region 212SD.

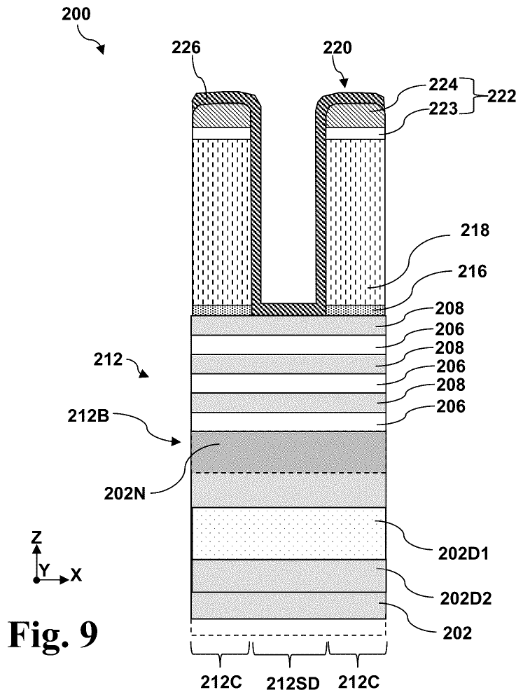

Referring to FIGS. 1 and 9, at block 108, a gate spacer layer 226 is deposited over the WIP structure 200, including over the dummy gate stack 220. In some embodiments, the gate spacer layer 226 is deposited conformally over the WIP structure 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

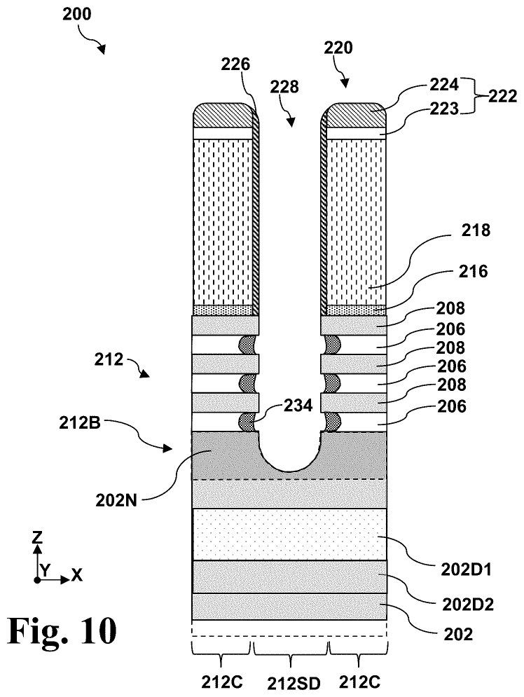

Referring to FIGS. 1 and 10, method 100 includes a block 110 where a source/drain region 212SD of the fin-shaped structure 212 is anisotropically recessed to form a source/drain trench 228. The anisotropic etch may include a dry etch or a suitable etch process that etches the source/drain regions 212SD and a portion of the substrate 202 below the source/drain regions 212SD. The resulting source/drain trench 228 extends vertically through the depth of the stack 204 and partially into the substrate 202. An example dry etch process for block 110 may implement an oxygen-containing gas, a fluorine-containing gas (e.g., CF₄, SF₆, CH₂F₂, CHF₃, C₄F₈, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 10, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202.

Referring to FIGS. 1 and 10, method 100 includes a block 112 where inner spacer features 234 are formed. While not shown explicitly, operation at block 112 may include selective and partial removal of the sacrificial layers 206 to form inner spacer recesses (shown as filled by inner spacer features 234 in FIG. 10), deposition of inner spacer material over the WIP structure 200, and etching back of the inner spacer material to form inner spacer features 234 (shown in FIG. 10). Referring to FIG. 10 the sacrificial layers 206 exposed in the source/drain trenches 228 are selectively and partially recessed to form inner spacer recesses (shown as filled by inner spacer features 234 in FIG. 10) while the gate spacer layer 226, the exposed portion of the substrate 202, and the channel layers 208 are substantially unetched. In an embodiment where the channel layers 208 consist essentially of silicon (Si) and sacrificial layers 206 consist essentially of silicon germanium (SiGe), the selective recess of the sacrificial layers 206 may be performed using a selective wet etch process or a selective dry etch process. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

After the inner spacer recesses are formed, an inner spacer material is deposited over the WIP structure 200, including over the inner spacer recesses. The inner spacer material may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material may be a single layer or a multilayer. In some implementations, the inner spacer material may be deposited using CVD, PECVD, SACVD, ALD or other suitable methods. The inner spacer material is deposited into the inner spacer recesses as well as over the sidewalls of the channel layers 208 exposed in the source/drain trenches 228. Referring to FIG. 10, the deposited inner spacer material is then etched back to remove the inner spacer material from the sidewalls of the channel layers 208 to form the inner spacer features 234 in the inner spacer recesses. At block 112, the inner spacer material may also be removed from the top surfaces and/or sidewalls of the gate-top hard mask layer 222 and the gate spacer layer 226. As shown in FIG. 10, each of the inner spacer features 234 is in direct contact with the recessed sacrificial layers 206 and is disposed vertically (along the Z direction) between two neighboring channel layers 208.

While not explicitly shown, before any of the epitaxial layers are formed, method 100 may include a cleaning process to clean surfaces of the WIP structure 200. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

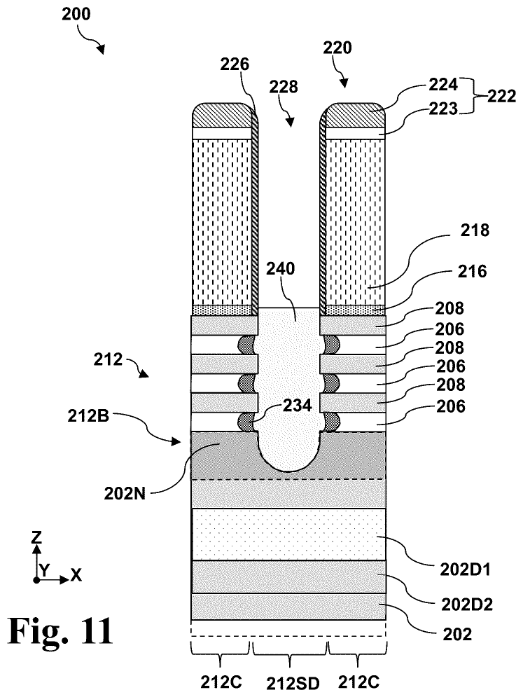

Referring to FIGS. 1 and 11, method 100 includes a block 114 where a source/drain feature 240 is formed over the source/drain region 212D. The source/drain feature 240 may be n-type or p-type. When the source/drain feature 240 is n-type, it may include silicon (Si) and an n-type dopant, such as phosphorus (P), arsenic (As), antimony (Sb), or a combination thereof. When the source/drain feature 240 is p-type, it may include silicon germanium (SiGe) and a p-type dopant, such as boron (B) or boron difluoride (BF₂). In some embodiments, the source/drain feature 240 may include multiple epitaxial layers with different dopant concentrations. In some implementations, the source/drain feature 240 may be deposited using a molecular beam epitaxy (MBE) process, a vapor phase deposition (VPE) process, and/or other suitable epitaxial growth processes.

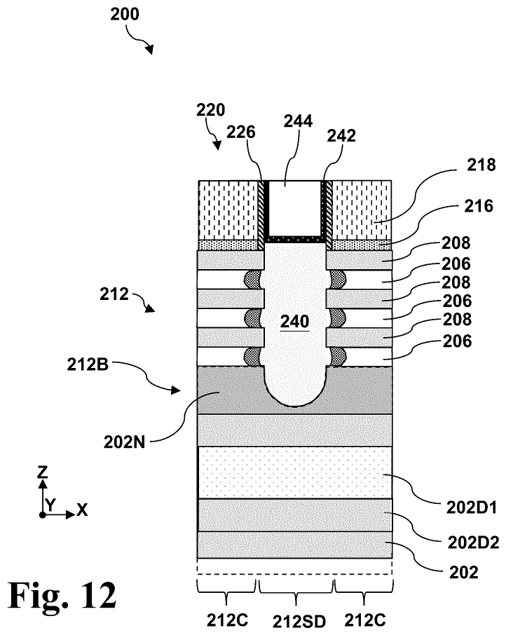

Referring to FIGS. 1 and 12, method 100 includes a block 116 where a contact etch stop layer (CESL) 242 and an interlayer dielectric (ILD) layer 244 are deposited. Referring to FIG. 11, the CESL 242 is deposited over the WIP structure 200, including over the source/drain feature 240. The CESL 242 may include silicon nitride or aluminum nitride. In some implementations, the CESL 242 may be deposited using CVD or ALD. The ILD layer 244 is then deposited over the CESL 242. In some embodiments, the ILD layer 244 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 244 may be deposited using CVD, FCVD, spin-on coating, or a suitable deposition technique. After the deposition of the ILD layer 244, the WIP structure 200 may be planarized by a planarization process to expose the dummy gate stack 220.

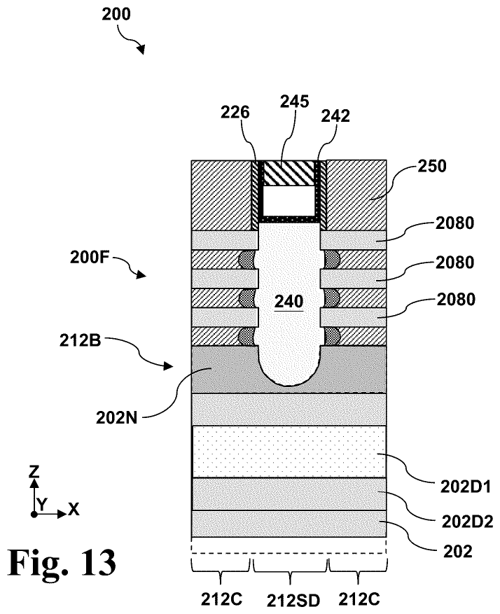

To protect the ILD layer 244 from being etched during the channel release process, a capping layer 245 is formed over the ILD layer 244. In an example process, the ILD layer 244 is anisotropically and selectively recessed to form a top recess (shown in FIG. 13 as being filled by the capping layer 245. In some embodiments, the anisotropic etch of the ILD layer 244 may include use of plasma of a fluorine-containing gas (e.g., CF₄, SF₆, CH₂F₂, CHF₃, C₂F₆, and/or C₃F₆). In some embodiments, the capping layer 245 may include a dielectric material that allows selective etching of dummy electrode layer 218, the dummy dielectric layer 216, and the sacrificial layers 206. In some embodiments, the capping layer 245 may include silicon nitride. The capping layer 245 functions to protect the ILD layer 244 from being damaged during the removal of sacrificial layers 206. A planarization process is performed to remove excess capping layer 245 and to expose the dummy gate stack 220. After the planarization, top surfaces of the capping layer 245, the CESL 242, the gate spacer layer 226, and the dummy gate stacks 220 are coplanar.

Referring to FIGS. 1 and 13, method 100 includes a block 118 where the plurality of channel layers 208 are released as channel members 2080. Operations at block 124 may include removal of the dummy gate stack 220 and selective removal of the sacrificial layers 206 to release the channel layers 208 (shown in FIG. 12). Reference is made to FIG. 3. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. After the removal of the dummy gate stack 220, sidewalls of the channel layers 208 and the sacrificial layers 206 in the channel region 212C are exposed. The sacrificial layers 206 between the channel layers 208 in the channel region 212C are selectively removed. The selective removal of the sacrificial layers 206 releases the channel layers 208 to form channel members 2080 shown in FIG. 13. The selective removal of the sacrificial layers 206 forms a gate trench 246 that includes spaces between adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

Referring to FIGS. 1 and 13, method 100 includes a block 120 where a gate structure 250 is formed to wrap around each of released as channel members 2080. After the release of the channel members 2080, the gate structure 250 is formed to wrap around each of the channel members 2080. While not explicitly shown, the gate structure 250 includes an interfacial layer interfacing the channel members 2080 and the substrate 202 in the channel region 212C, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation or thermal oxidation. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer may be formed by ALD, physical vapor deposition (PVD), CVD, oxidation, and/or other suitable methods.

The gate electrode layer of the gate structure 250 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. The gate structure includes portions that interpose between channel members 2080 in the channel region 212C.

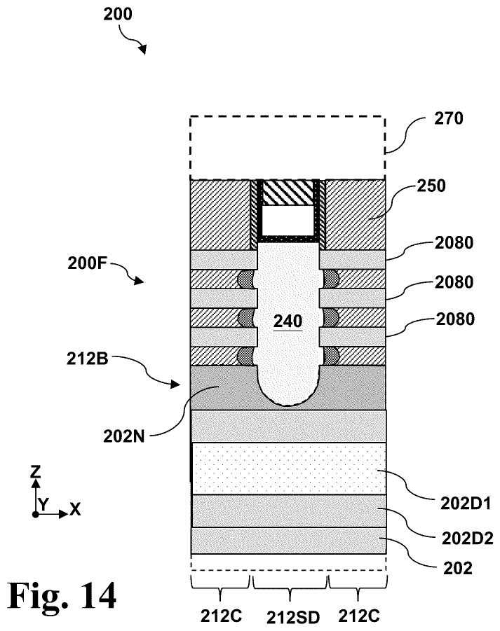

Referring to FIGS. 1 and 14, method 100 includes a block 122 where a frontside interconnect structure 270 is formed. The frontside interconnect structure 270 includes via and contact features that provide vertical connections and conductive lines that provide horizontal connections. In some implementations, the frontside interconnect structure 270 may include eight (8) to twenty (20) levels of metal layers (or metallization layers) to route signal. Each of the metal layers in the frontside interconnect structure 270 may include an etch stop layer (ESL) and an intermetal dielectric (IMD) layer disposed on the ESL. The ESLs may share the same composition and may include silicon nitride or silicon oxynitride. The IMD layers may share the same composition and may include silicon oxide, tetraethylorthosilicate (TEOS) oxide, un-doped silicate glass (USG), or doped silicon oxide such as borophosphosilicate glass (BPSG), fused silicate glass (FSG), phosphosilicate glass (PSG), boron doped silicate glass (BSG), low-k dielectric material, other suitable dielectric material, or combinations thereof. Example low-k dielectric materials include carbon doped silicon oxide, Xerogel, Aerogel, amorphous fluorinated carbon, benzocyclobutene (BCB), or polyimide. The metal lines and vias in the metal layers may include titanium (Ti), ruthenium (Ru), nickel (Ni), cobalt (Co), copper (Cu), molybdenum (Mo), tungsten (W), aluminum (Al), and/or other suitable materials.

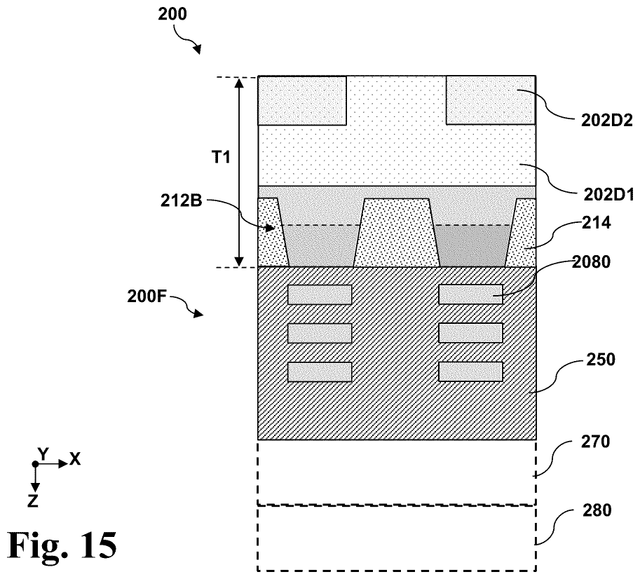

Referring to FIGS. 1 and 15-20, method 100 includes a block 124 where backside devices 200B1-200B5 are formed over the dopant implantation profile. Formation of the backside devices requires flipping the WIP structure 200 upside down. To provide mechanical strength when the substrate 202 is ground away, a carrier substrate 280 is bonded over a top surface of the frontside interconnect structure 270. In some embodiments, the carrier substrate 280 may include silicon, quartz, or glass. In one embodiment, the carrier substrate 280 includes silicon. The carrier substrate 280 may be bonded to the frontside interconnect structure 270 by an adhesive film or a pair of bonding layers. For case of illustration, the bonding structures between the carrier substrate 280 and the frontside interconnect structure 270 are omitted from FIGS. 15-20 and thicknesses of the frontside interconnect structure 270 and the carrier substrate 280 are not drawn to scale. After the WIP structure 200 is flipped over, as shown in FIG. 15, the substrate 202 is subject to grinding and polishing processes until the ion implantation profile formed block 102 is exposed. In some implementation, after the grinding process to expose the ion implantation profile, the substrate 202 has a first thickness T1, which may be between about 100 nm and about 300 nm.

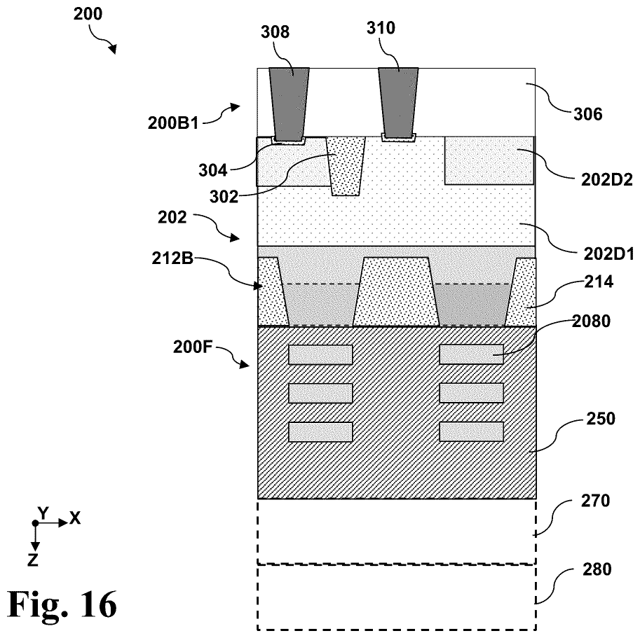

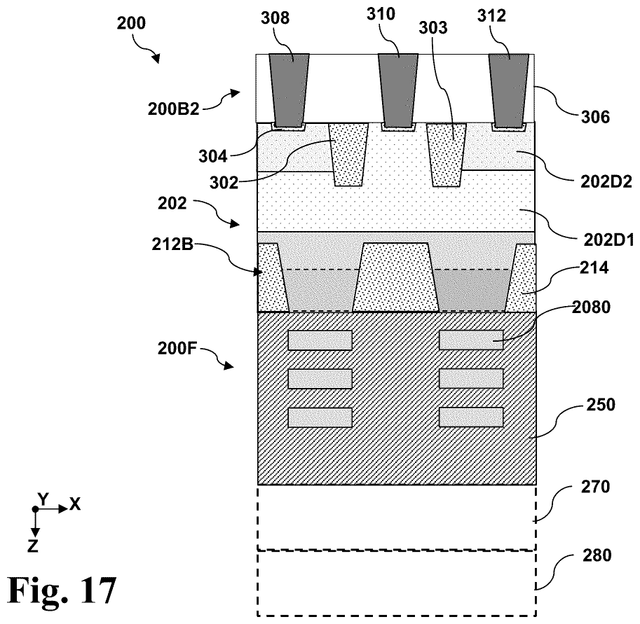

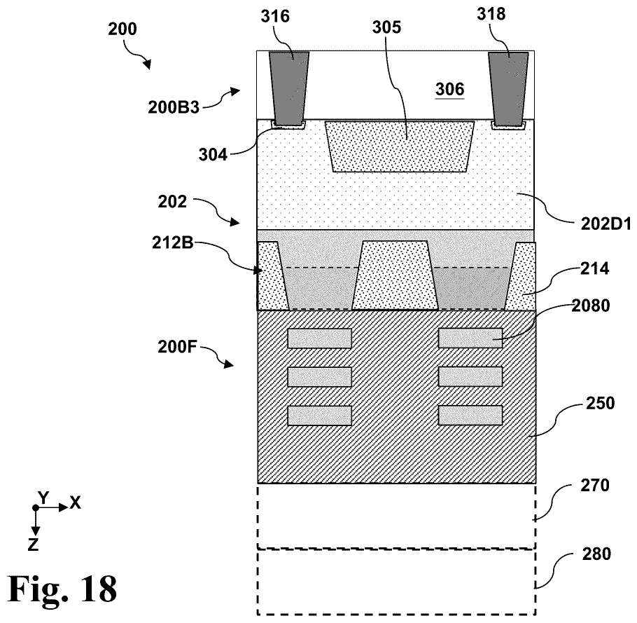

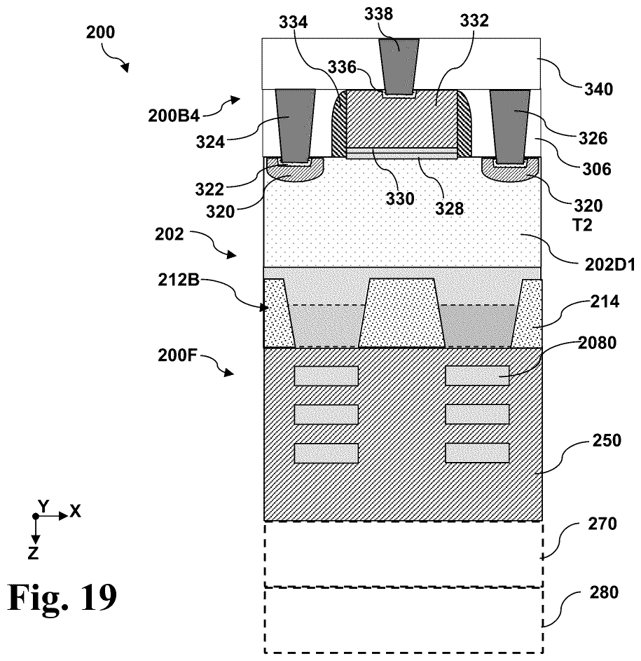

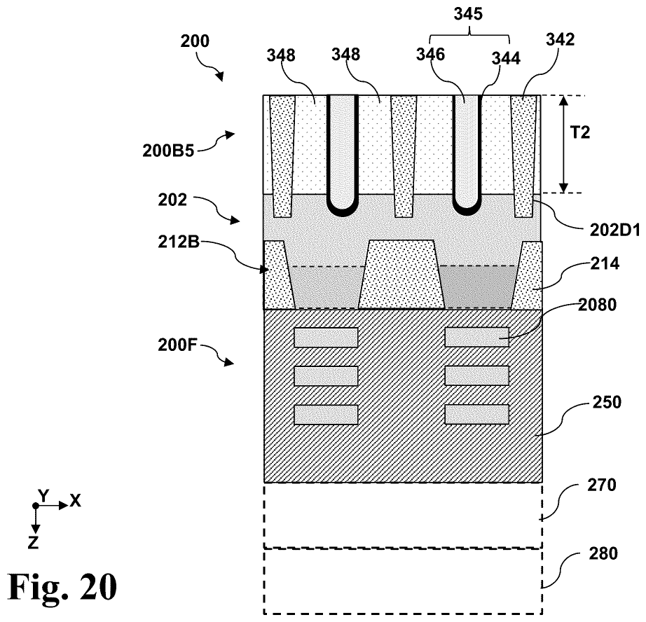

The present disclosure envisions formation of different types of backside devices, some of which are illustrated in FIGS. 16-20. FIG. 16 illustrates formation of a first backside device 200B1, which may be a diode. FIG. 17 illustrates formation of a second backside device 200B2, which may be a bipolar junction transistor (BJT). FIG. 18 illustrates formation of a third backside device 200B3, which may be a resistor. FIG. 19 illustrates formation of a fourth backside device 200B4, which is a planar transistor. FIG. 20 illustrates formation of a fifth backside device 200B5, which is an embedded dynamic random access memory (eDRAM device).

Reference is first made to FIG. 16, which illustrates the first backside device 200B1 formed over the ion implantation profile. To form the first backside device 200B1, a first backside isolation feature 302 is formed along a vertical interface between the first-type dopant region 202D1 and the second-type dopant region 202D2. In an example process, a trench is formed along the vertical interface between the first-type dopant region 202D1 and the second-type dopant region 202D2. A dielectric material is deposited over the back side, including over the trench, and then the dielectric material is planarized until the first-type dopant region 202D1 and the second-type dopant region 202D2 are exposed again. In some implementations, the dielectric material may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The first backside isolation feature 302 may also be referred to as the first backside shallow trench isolation (STI) 302. As shown in FIG. 16, a depth of the first backside isolation feature 302 is selected such that the n-p or p-n junction between the first-type dopant region 202D1 and the second-type dopant region 202D2 is substantially along the X-Y plane, which is the plane parallel to a back surface of the substrate 202.

A backside dielectric layer 306 is deposited over the backside isolation feature 302, the first-type dopant region 202D1 and the second-type dopant region 202D2. In some instances, a composition of the backside dielectric layer 306 may be similar to that of the ILD layer 244. After the formation of the backside dielectric layer 306, two contact openings are formed through the backside dielectric layer 306, one exposing the first-type dopant region 202D1 and the other exposing the second-type dopant region 202D2. After formation of the contact openings, silicide layers 304 are formed over the exposed areas of the first-type dopant region 202D1 and the other exposing the second-type dopant region 202D2. In some implementations, the silicide layers 304 may include nickel silicide (NiSi), cobalt silicide (CoSi), or titanium silicide (TiSi). In one embodiment, the silicide layer 304 includes nickel silicide. A first contact feature 308 and a second contact feature 310 are then formed by depositing a metal fill layer over the two contact openings and removing excess material by planarization. In some instances, the metal fill layer may include tungsten (W), ruthenium (Ru), cobalt (Co), or copper (Cu). In one embodiment, the metal fill layer may be cobalt (Co). In some embodiments illustrated in FIG. 16, the first contact feature 308 is electrically coupled to the second-type dopant region 202D2 and the second contact feature 310 is electrically coupled to the first-type dopant region 202D1 by way of the silicide layer 304.

Reference is then made to FIG. 17, which illustrates the second backside device 200B2 formed over the ion implantation profile. In the depicted embodiment, the second backside device 200B2 is a bipolar junction transistor that includes two p-n (or n-p) junctions, instead of only one in the first backside device 200B1. As illustrated in FIG. 17, in addition to the first backside isolation feature 302, a second backside isolation feature 303 is also formed along a vertical interface between the first-type dopant region 202D1 and the second-type dopant region 202D2. The first backside isolation feature 302 and the second backside isolation feature 303 provide isolation among the three terminals of second backside device 200B2. Besides the first contact feature 308 and the second contact feature 310 described above with respect to the first backside device 200B1, the second backside device 200B2 also includes a third contact feature 312 coupled to another portion of the second-type dopant region 202D2 by way of the silicide layer 304. In some instances, the second contact feature 310 may serve as a base of a bipolar junction transistor while the first contact feature 308 and the third contact feature 312 may serve as the collector and emitter. The second backside isolation feature 303 and the third contact feature 312 may be formed using similar processes used to the first backside isolation feature 302 and the first contact feature 308. Detailed description thereof is omitted for brevity.

Reference is now made to FIG. 18, which illustrates the third backside device 200B3 formed over only the first-type dopant region 202D1. Instead of the first isolation feature 302 and the second backside isolation feature 303 shown in FIGS. 16 and 16, a longer block isolation feature 305 is formed in the first-type dopant region 202D1 to increase a conduction path between two resistor electrodes. In the depicted embodiments, a fourth contact feature 316 and a fifth contact feature 318 are formed through the backside dielectric layer 306. The fourth contact feature 316 and the fifth contact feature 318 are electrically coupled to the two regions of the first-type dopant region 202D1 by way of a silicide layer 304. As shown in FIG. 18, the two regions are separated by the block isolation feature 305 along the X direction and a length of the block isolation feature 305 defines a length of the conduction path between the two regions that are coupled to the fourth contact feature 316 and the fifth contact feature 318, respectively. It can be seen that, provided sufficient space, the length of the block isolation feature 305 determines a resistance of the third backside device 200B3, which functions as a resistor.

Reference is made to FIG. 19, which illustrates the fourth backside device 200B4 formed over only the first-type dopant region 202D1. In some implementations, the first-type dopant region 202D1 includes a p-type dopant. In an example process to form the fourth backside device 200B4, an interfacial layer 328, a gate dielectric layer 330, and a polysilicon electrode layer 332 are deposited over the first-type dopant region 202D1. In some instances, the interfacial layer 328 includes silicon oxide or silicon oxynitride; the gate dielectric layer 330 is formed of a high-k dielectric material such as hafnium oxide; and the polysilicon gate 332 includes polysilicon and an n-type dopant, such as phosphorus (P). In some alternative embodiments, the polysilicon gate 332 may be replaced with a metal gate formed of titanium nitride. The interfacial layer 328, the gate dielectric layer 330 and the polysilicon electrode layer 332 are then patterned to form a gate structure. A gate spacer layer 334 is conformally deposited over the gate structure and the first-type dopant region 202D1. The gate spacer layer 334 is then anisotropically etched to form the gate spacer shown in FIG. 19 that lines sidewalls of the gate structure. The first source/drain region 320 and the second source/drain feature 322 may be formed by ion implantation or an epitaxial deposition process. In the depicted embodiments, the first source/drain region 320 and the second source/drain feature 322 are epitaxially deposited and include silicon (Si) and an n-type dopant, such as phosphorus (P). After the backside dielectric layer 306 is formed over the first source/drain feature 320 and the second source/drain feature 322, a sixth contact feature 324 and a seventh contact feature 326 are formed through the backside dielectric layer 306 to couple to the first source/drain region 320 and the second source/drain region 322 by way of a silicide feature. A backside isolation layer 340 is formed over the sixth contact feature 324 and the seventh contact feature 326. A composition of the backside isolation layer 340 may be similar to the backside dielectric layer 306. A backside gate contact 338 is then formed through the backside isolation layer 340 to contact the polysilicon electrode layer 332 by way of a silicide feature 336. When the sixth contact feature 324 and the seventh contact feature 326 are pulled to the same potential, the fourth backside device 200B4 functions as a capacitor where the interfacial layer 328 and the gate dielectric layer 330 function as a capacitor insulator. The backside gate contact 338 functions as an electrode while the sixth contact feature 324 and the seventh contact feature 326 collectively function as another electrode. When the sixth contact feature 324 and the seventh contact feature 326 are not coupled together, the fourth backside device 200B4 functions as a planar device. In some instances, the planar device implemented using the fourth backside device 200B4 may function as a backside header device or backside header switch to activate different blocks of FEOL transistors.

Reference is now made to FIG. 20, which illustrates the fifth backside device 200B5 formed over only the first-type dopant region 202D1. The fifth backside device 200B5 shown in FIG. 20 may be a low-leakage transistor in a 1-transistor-1-capacitor (1T1C) embedded dynamic random access memory (eDRAM) cell. In an example process, isolation trenches and gate trenches are formed through the first-type dopant region 202D1. The isolation trenches are formed completely through the first-type dopant implantation profile to ensure that the resulting isolation structure satisfactorily isolates individual low-leakage transistor. After formation of the isolation trenches and gate trenches, a dielectric material is deposited into isolation trenches to form isolation features 342 shown in FIG. 20. In some implementations, the dielectric material for the isolation feature 342 may include silicon oxide or a low-k dielectric material. A gate dielectric layer 344 is deposited over the gate trenches. In some embodiments, the gate dielectric layer 344 may include hafnium oxide. A gate electrode 346 is then deposited over the gate dielectric layer 344. In some implementations, the gate electrode 346 may include tungsten (W), ruthenium (Ru), cobalt (Co), or titanium nitride (TiN). The gate electrode 346 and the gate dielectric layer 344 constitute a long gate structure 345 that engages a length of the first-type dopant region 202D1. One of the two source/drain nodes 348 divided by the long gate structure 345 is coupled to a capacitor to function as a storage node. It is noted that both the isolation feature 342 and the long gate structure 345 may extend completely through a second thickness T2 of the first-type dopant region 202D1. In some instances, the second thickness T2 may be between about 50 nm and about 200 nm. While not explicitly shown in the figures, the capacitor for the 1T1C eDRAM cell may include a deep trench capacitor.

Attention is now turned to method 400 in FIG. 21.

Referring to FIGS. 21 and 22-24, method 400 includes a block 402 where a dopant implantation profile is formed in a substrate 202. Operations at block 402 are substantially similar to those at block 102 and will not be repeated here for brevity.

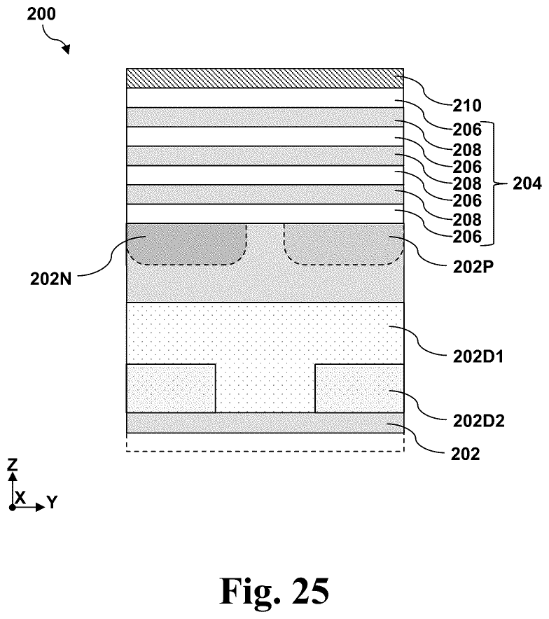

Referring to FIGS. 21 and 25, method 400 includes a block 404 where a stack 204 of alternating semiconductor layers is formed over the WIP structure 200. Operations at block 404 are substantially similar to those at block 104 described above. Accordingly, detailed description of the operations at block 404 are omitted for brevity.

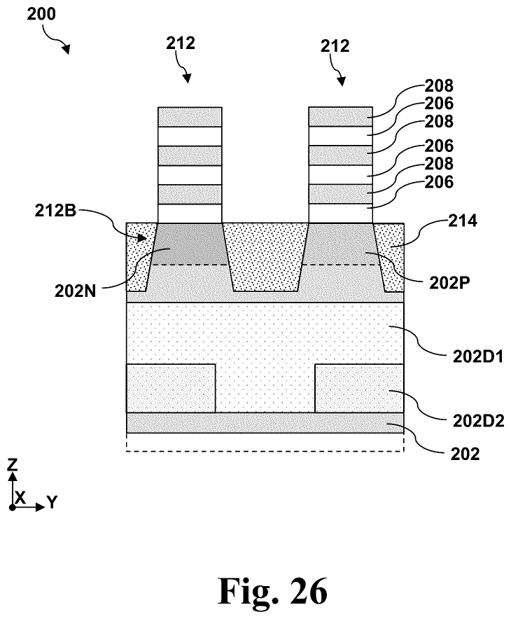

Referring to FIGS. 21 and 26, method 400 includes a block 406 where a fin-shaped structure 212 is formed from the stack 204 and the substrate 202. Operations at block 406 are substantially similar to those at block 106 described above. Accordingly, detailed description of the operations at block 406 are omitted for brevity.

Referring to FIGS. 21 and 27-29, method 400 includes a block 408 where a dummy gate stack 220 is formed over a channel region 212C of the fin-shaped structure 212. Operations at block 408 are substantially similar to those at block 108 described above. Accordingly, detailed description of the operations at block 408 are omitted for brevity.

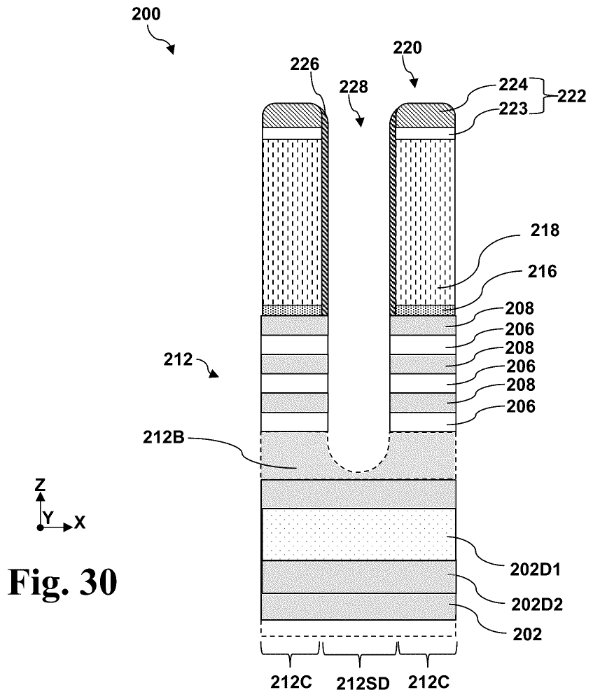

Referring to FIGS. 21 and 30, method 400 includes a block 410 where a source/drain region 212SD of the fin-shaped structure 212 is anisotropically recessed to form a source/drain trench 228. Operations at block 410 may be substantially similar to those at block 110 described above. Accordingly, detailed description of the operations at block 410 are omitted for brevity.

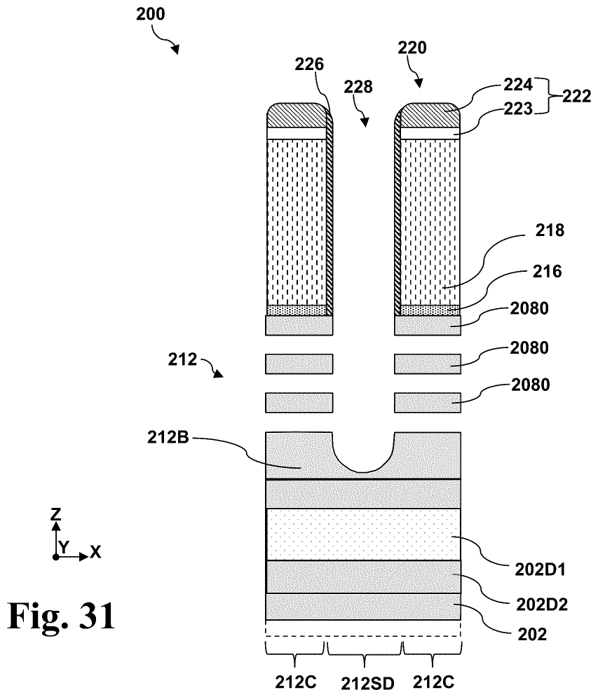

Referring to FIGS. 21 and 31, method 400 includes a block 412 where the plurality of channel layers 208 in the channel regions are released as channel members 2080. After the formation of the source/drain trench 228, the sacrificial layers 206 interleaving the channel layers 208 in the channel region 212C are selectively removed. The selective removal of the sacrificial layers 206 releases the channel layers 208 (shown in FIG. 30) to form channel members 2080 shown in FIG. 31. The selective removal of the sacrificial layers 206 forms spaces between and around adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

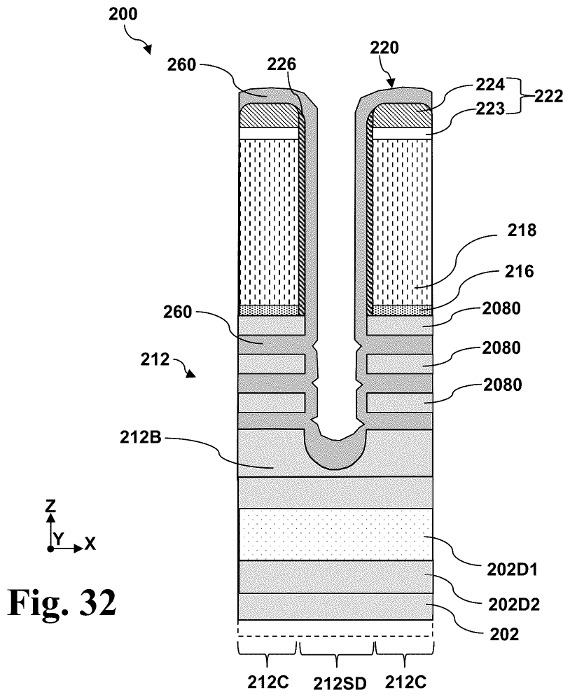

Referring to FIGS. 21 and 32, method 400 includes a block 414 where a dummy layer 230 is deposited around the channel members 2080 and over the source/drain trenches 228. The dummy layer 230 may include silicon oxide and may be deposited using plasma enhanced chemical vapor deposition (PECVD) or ALD. As shown in FIG. 32, the dummy layer 230 fills the spaces among the channel members 2080 and covers end sidewalls of the channel members 2080. Additionally, the dummy layer 230 is in direct contact with a sidewall of the gate spacer layer 226 and a top surface of the substrate 202. Depending on the design, the channel members 2080 may take form of nanowires, nanosheets, or other nanostructures.

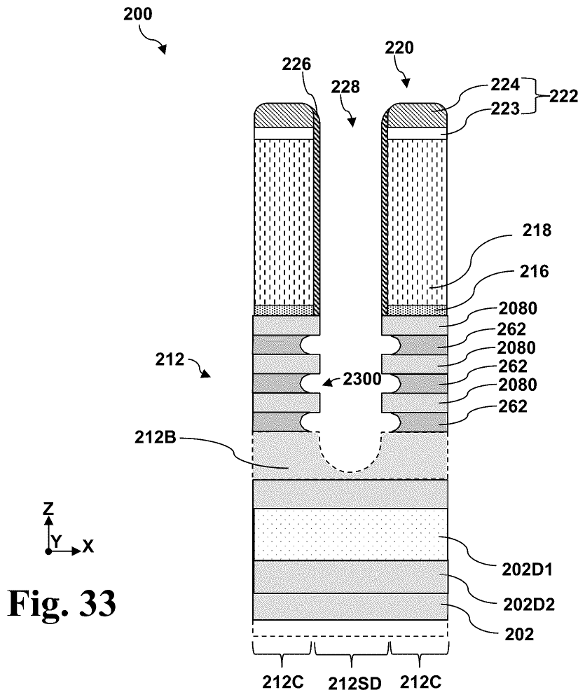

Referring to FIGS. 21, 33 and 34, method 400 includes a block 416 where inner spacer features 234 are formed. Referring to FIG. 33, the dummy layers 230 are selectively and partially recessed to form inner spacer recesses 232 while the gate spacer layer 226, the dummy gate stack 220, the exposed portion of the substrate 202, and the channel layers 208 are substantially unetched. In an embodiment where the channel layers 208 consist essentially of silicon (Si) and the dummy layers 230 are formed of silicon oxide, the selective recess of the dummy layer 230 may be performed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof.

To form the inner spacer features, an inner spacer layer is deposited over WIP structure 200, including over the source/drain trench 228 and the inner spacer recesses 232. In some embodiments, the inner spacer layer may include silicon carbonitride (SiCN), silicon oxycarbonitride (SiOCN), silicon nitride (SiN), silicon oxycarbide (SiOC), or silicon oxynitride (SiON). In some implementations, the inner spacer layer may be deposited using CVD or ALD. The deposited inner spacer layer is then etched back to form inner spacer features 234 in the inner spacer recesses 232. In some embodiments, the etching back may include use of a dry etch process, such as a reactive ion etching (RIE) process that is aided by plasma. An example dry etch process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof.

While not explicitly shown, before any of the epitaxial layers are formed, method 300 may include a cleaning process to clean surfaces of the WIP structure 200, especially surfaces of the channel members 2080 and the substrate 202. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

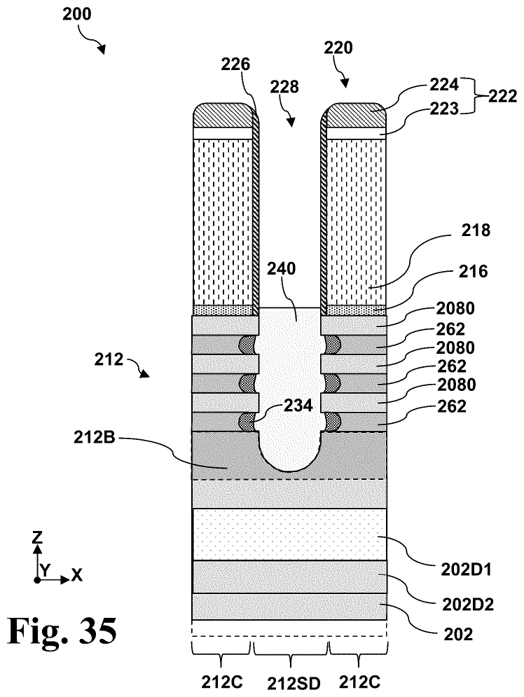

Referring to FIGS. 21 and 35, method 400 includes a block 418 where a source/drain feature 240 is formed over the source/drain region 212SD. While not explicitly shown in the figures, the source/drain feature 240 may include a bottom epitaxial feature and a main epitaxial feature over the bottom epitaxial feature. The source/drain feature 240 may be n-type or p-type. When the source/drain feature 240 is n-type, the bottom epitaxial feature may include undoped silicon (Si) or undoped silicon germanium (SiGe) and the main epitaxial feature may include silicon (Si) and an n-type dopant, such as phosphorus (P), arsenic (As), antimony (Sb), or a combination thereof. When the source/drain feature 240 is p-type, the bottom epitaxial feature may include undoped silicon (Si) or undoped silicon germanium (SiGe) and the main epitaxial feature may include silicon germanium (SiGe) and a p-type dopant, such as boron (B), boron difluoride (BF₂), or a combination thereof. As used herein, the undoped semiconductor material is regarded as undoped when it is not intentionally doped. In some alternative embodiments, the bottom epitaxial feature may include a counter dopant to reduce leakage into the bulk substrate 202. For example, the bottom epitaxial feature in an n-type source/drain feature 240 may include a p-type dopant, such as boron (B). For another example, the bottom epitaxial feature in a p-type source/drain feature 240 may include an n-type dopant, such as phosphorus (P), arsenic (As), or antimony (Sb). The source/drain feature 240 may be formed using vapor-phase epitaxy (VPE), ultra-high vacuum CVD (UHV-CVD), or molecular beam epitaxy (MBE). Doping of the source/drain features 240 may be achieved with in-situ doping.

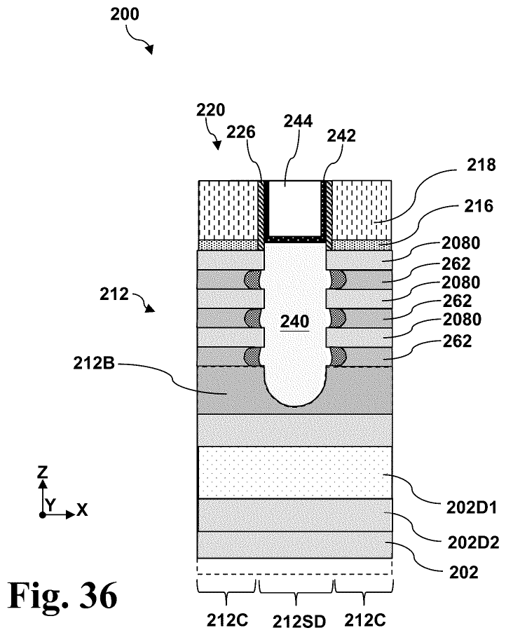

Referring to FIGS. 21 and 36, method 400 includes a block 420 where a contact etch stop layer (CESL) 242 and an interlayer dielectric (ILD) layer 244 are deposited. At block 420, the CESL 242 is deposited over the WIP structure 200, including over the source/drain feature 240. The CESL 242 may include silicon nitride or aluminum nitride. In some implementations, the CESL 242 may be deposited using CVD or ALD. The ILD layer 244 is then deposited over the CESL 242. In some embodiments, the ILD layer 244 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 244 may be deposited using CVD, FCVD, spin-on coating, or a suitable deposition technique. After the deposition of the ILD layer 244, the WIP structure 200 may be planarized by a planarization process to expose the dummy gate stack 220. After the planarization process, top surfaces of the dummy gate stack 220, the CESL 242, the ILD layer 244, and the gate spacer layer 226.

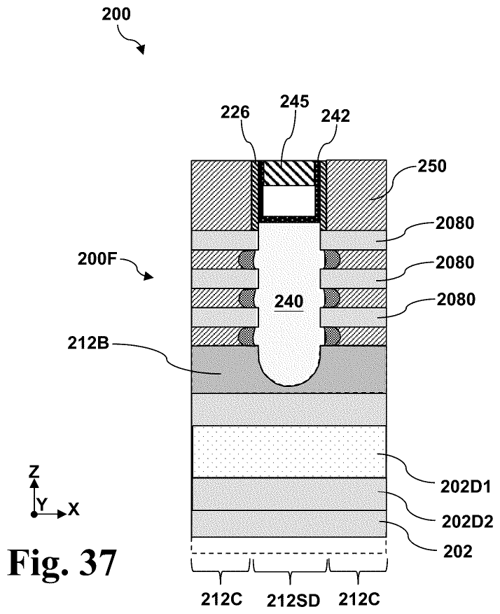

Referring to FIGS. 21 and 37, method 400 includes a block 422 wherein the dummy gate stack 220 and the dummy layers 230 are replaced with a gate structure 250. In order to protect the ILD layer 244 from being damaged when the dummy layers 230 are removed, the ILD layer 244 is anisotropically and selectively recessed to form a top recess (shown as being filled with capping layer 245 in FIG. 37). In some embodiments, the anisotropic etch of the ILD layer 244 may include use of plasma of a fluorine-containing gas (e.g., CF₄, SF₆, CH₂F₂, CHF₃, C₂F₆, and/or C₃F₆). A dielectric material is deposited over the top recess and planarized to form a capping layer 245. In some implementations, the capping layer 245 may include silicon nitride. Due to the planarization process, top surfaces of the capping layer 245, the CESL 242, the gate spacer layer 226, and the dummy gate stacks 220 are coplanar.

After formation of the capping layer 245, the dummy gate stack 220 is removed. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. After the removal of the dummy gate stack 220, the channel members 2080 and the dummy layer 230 in the channel region 212C are exposed. After the removal of the dummy gate stack 220, a separate etch process may be performed to selectively remove the dummy layer 230 in the channel region 212C. For example, a selective wet etch process or a selective dry etch process may be performed to remove the dummy layer 230. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. In one embodiment, a selective wet etch process is implemented at block 422. After the selective removal of the dummy layer 230, the channel members 2080 in the channel region 212C are once again exposed.

After the release of the channel members 2080, the gate structure 250 is formed to wrap around each of the channel members 2080 as shown in FIG. 37. While not explicitly shown, the gate structure 250 includes an interfacial layer interfacing the channel members 2080 and the substrate 202 in the channel region 212C, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer may be formed by ALD, physical vapor deposition (PVD), CVD, oxidation, and/or other suitable methods.

The gate electrode layer of the gate structure 250 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. The gate structure 250 includes portions that interpose between channel members 2080 in the channel region 212C. In some embodiments, the gate structure 250 may include a p-type gate structure portion and an n-type gate structure portion. The p-type gate structure portion includes p-type work function metal layers disposed closer to the channel members 2080. The n-type gate structure portion includes n-type work function metal layers disposed closer to the channel members 2080.

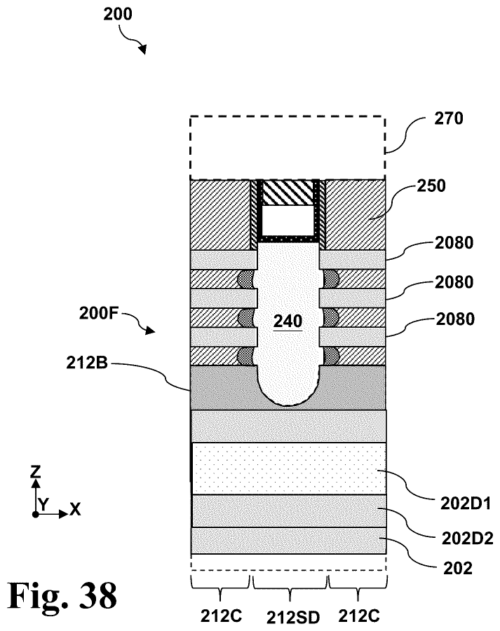

Referring to FIGS. 21 and 38, method 400 includes a block 424 where a frontside interconnect structure 270 is formed. Operations at block 424 may be substantially similar to those at block 122 described above. Accordingly, detailed description of the operations at block 424 are omitted for brevity.

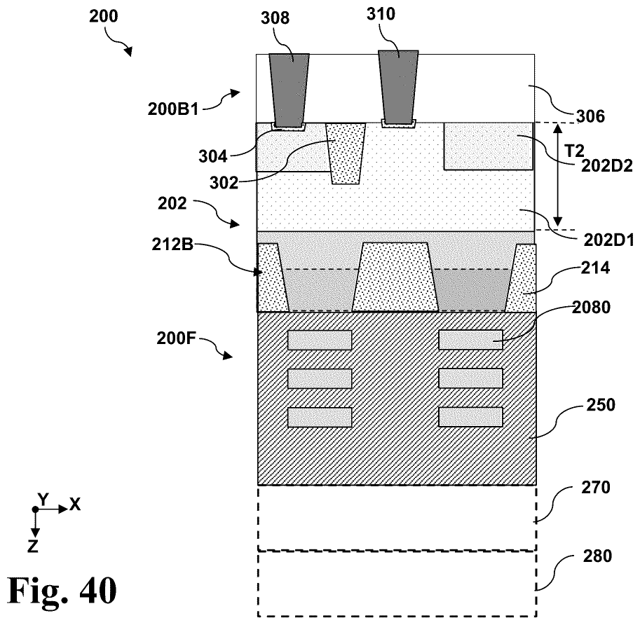

Referring to FIGS. 21 and 39-44, method 400 includes a block 426 where backside devices 200B1-200B5 are formed over the dopant implantation profile. Operations at block 426 may be substantially similar to those at block 124 described above. Additionally, the backside devices 200B1, 200B2, 200B3, 200B4, and 200B5 shown in FIGS. 40-44 may be substantially similar to the backside devices 200B1, 200B2, 200B3, 200B4, and 200B5 shown in FIGS. 16-20. Accordingly, detailed description of the operations at block 426 and backside devices formed therefrom are omitted for brevity.

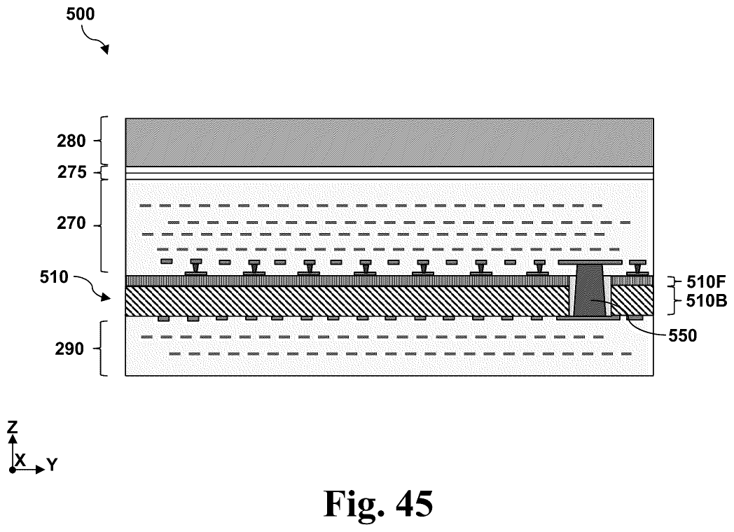

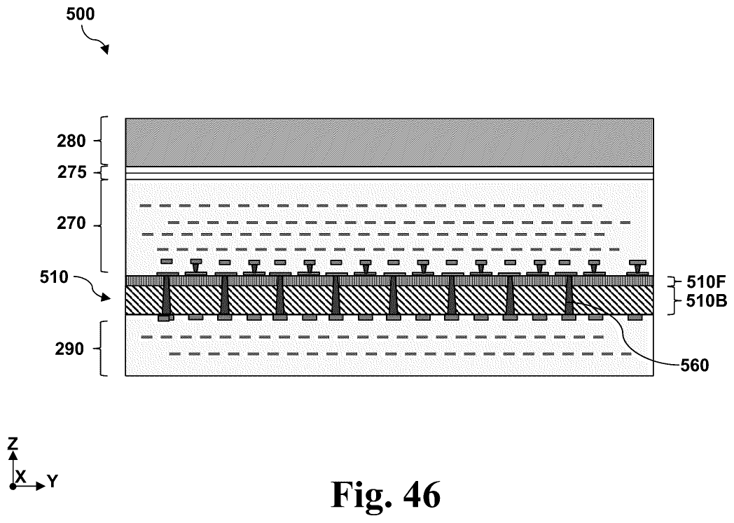

FIGS. 45 and 46 illustrate cross-sectional views of device dies 500 that include backside devices formed using method 100 or 400 described above. Reference is first made to FIG. 45. The device die 500 in FIG. 45 includes a substrate 510 that includes frontside devices 510F and backside devices 510B. The frontside devices 510F include FEOL devices. The backside devices 510B may include the backside devices 200B1, 200B2, 200B3, 200B4, and 200B5 formed using method 100 or 400 described above. A frontside interconnect structure 270 is disposed over a front side of the substrate 510. A backside interconnect structure 290 is disposed over a back side of the substrate 510. A carrier substrate 280 is bonded to a top surface of the frontside interconnect structure 270 by way of a pair of bonding layers 275. In some embodiments, the device die 500 includes micron-size through-substrate-via (TSV) 550 that extends through the substrate 510 to route power supply signal from the front side of the substrate 510 to the back side of the substrate 510. In some embodiments, the micron-size TSV 550 includes a diameter or width between about 0.3 μm and about 0.8 μm and a vertical length between about 3 μm and about 7 μm. The device die 500 in FIG. 46 is similar to the device die 500 in FIG. 45, except that the micron-size TSVs 550 are replaced with nano-size TSVs 560. Like the micron-size TSVs 550, the nano-size TSVs 560 also function to route power supply signal from the front side of the substrate 510 to the back side of the substrate 510. In some embodiments, the nano-size TSV 560 includes a diameter or width between about 50 nm and about 150 nm and a vertical length between about 300 nm and about 500 nm.

In one exemplary aspect, the present disclosure is directed to a device structure. The device structure includes a substrate having a front side and a back side, a fin structure over the front side, a plurality of nanostructures disposed over the fin structure, a gate structure wrapping around each of the plurality of nanostructures, a first doped region disposed over the back side of the substrate, a backside dielectric layer over the first doped region, and a first contact feature extending through the backside dielectric layer to interface the first doped region.

In some embodiments, the device structure further includes a silicide layer sandwiched between the first contact feature and the first doped region. In some implementations, the device structure further includes a second contact feature extending through the backside dielectric layer to interface the first doped region, an electrode disposed in the backside dielectric layer between the first contact feature and the second contact feature, an interfacial layer disposed between the electrode and the first doped region, and a high-k dielectric layer dispose between the interfacial layer and the electrode. In some embodiments, the electrode includes titanium nitride or polysilicon. In some instances, the interfacial layer includes silicon oxynitride. In some embodiments, the high-k dielectric layer includes hafnium oxide. In some embodiments, the device structure further includes a spacer layer disposed along sidewalls of the electrode, the interfacial layer, and the high-k dielectric layer.

In another exemplary aspect, the present disclosure is directed to a device structure. The device structure includes a substrate having a front side and a back side, a plurality of nanostructures disposed over the front side, a gate structure wrapping around each of the plurality of nanostructures, a frontside interconnect structure disposed over the gate structure and the plurality of nanostructures, a first doped region disposed over the back side of the substrate, and a backside device disposed over the first doped region.

In some embodiments, the device structure further includes a backside dielectric layer disposed over the first doped region, a first contact feature and a second contact feature extending through the backside dielectric layer to interface the first doped region, an electrode disposed in the backside dielectric layer between the first contact feature and the second contact feature, an interfacial layer disposed between the electrode and the first doped region, and a high-k dielectric layer dispose between the interfacial layer and the electrode. In some implementations, the electrode includes titanium nitride or polysilicon. In some embodiments, the interfacial layer includes silicon oxynitride. In some embodiments, the high-k dielectric layer includes hafnium oxide. In some instances, each of the first contact feature and the second contact feature interfaces the first doped region by way of a silicide feature. In some embodiments, the device structure further includes a spacer layer disposed along sidewalls of the electrode, the interfacial layer, and the high-k dielectric layer.

In yet another exemplary aspect, the present disclosure is directed to a method. The method includes performing an ion implantation process to a substrate to form a doped region, forming over the substrate a stack that includes a plurality of channel layers interleaved by a plurality of sacrificial layers, patterning the stack and the substrate to form a fin-shaped structure having a base portion formed from the substrate and a stack portion formed from the stack, forming an isolation feature around the base portion, forming a dummy gate stack over a channel region of the fin-shaped structure, depositing a gate spacer layer over the dummy gate stack, after the depositing of the gate spacer layer, recessing a source/drain region of the fin-shaped structure to form a source/drain trench extending into the base portion, selectively removing the plurality of sacrificial layers in the channel region to release the plurality of channel layers as a plurality of channel members, depositing a dummy layer over the plurality of channel members, selectively and partially recessing the dummy layer to form inner spacer recesses among the plurality of channel members and a bottom dummy feature over a bottom surface of the source/drain trench. forming inner spacer features in the inner spacer recesses, forming a source/drain feature over the source/drain region, after the forming of the source/drain feature, removing the dummy gate stack, removing the dummy layer, forming a gate structure to wrap around each of the plurality of channel members, forming a frontside interconnect structure over the gate structure, and after the forming of the frontside interconnect structure, forming a backside device over the doped region.

In some embodiments, the forming of the backside device includes bonding a carrier substrate to the frontside interconnect structure, after the bonding, flipping the substrate upside down, forming an electrode over the doped region, depositing a backside dielectric layer over the doped region and the electrode, and forming a first contact feature and a second contact feature through the backside dielectric layer to interface the doped region. The electrode is disposed between the first contact feature and the second contact feature. In some implementations, the forming of the first contact feature and the second contact feature includes forming a first contact opening and a second contact opening through the backside dielectric layer to expose the doped region, forming a first silicide feature in the first contact opening and a second silicide feature in the second contact opening, and depositing a metal fill layer over the first silicide feature and the second silicide feature. In some embodiments, the method further includes before the forming of the electrode over the doped region, depositing an interfacial layer over the doped region. After the forming of the electrode, the interfacial layer is disposed between the doped region and the electrode. In some instances, the method further includes before the forming of the electrode over the doped region, depositing a high-k dielectric layer over the interfacial layer over the doped region. After the forming of the electrode, the interfacial layer and the high-k dielectric layer is disposed between the doped region and the electrode. In some embodiments, the backside device includes a diode, a bipolar junction transistor, a resistor, a capacitor, a metal oxide semiconductor transistor, or an embedded dynamic random access memory (eDRAM).

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A device structure, comprising:
a substrate having a front side and a back side;
a fin structure over the front side;
a plurality of nanostructures disposed over the fin structure;
a gate structure wrapping around each of the plurality of nanostructures;
a first doped region disposed over the back side of the substrate;
a backside dielectric layer over the first doped region; and
a first contact feature extending through the backside dielectric layer to interface the first doped region.

2. The device structure of claim 1, further comprising:
a silicide layer sandwiched between the first contact feature and the first doped region.

3. The device structure of claim 1, further comprising:
a second contact feature extending through the backside dielectric layer to interface the first doped region;
an electrode disposed in the backside dielectric layer between the first contact feature and the second contact feature;
an interfacial layer disposed between the electrode and the first doped region; and
a high-k dielectric layer dispose between the interfacial layer and the electrode.

4. The device structure of claim 3, wherein the electrode comprises titanium nitride or polysilicon.

5. The device structure of claim 3, wherein the interfacial layer comprises silicon oxynitride.

6. The device structure of claim 3, wherein the high-k dielectric layer comprises hafnium oxide.

7. The device structure of claim 3, further comprising a spacer layer disposed along sidewalls of the electrode, the interfacial layer, and the high-k dielectric layer.

8. A device structure, comprising:
a substrate having a front side and a back side;
a plurality of nanostructures disposed over the front side;
a gate structure wrapping around each of the plurality of nanostructures;
a frontside interconnect structure disposed over the gate structure and the plurality of nanostructures;
a first doped region disposed over the back side of the substrate; and
a backside device disposed over the first doped region.

9. The device structure of claim 8, further comprising:
a backside dielectric layer disposed over the first doped region;
a first contact feature and a second contact feature extending through the backside dielectric layer to interface the first doped region;
an electrode disposed in the backside dielectric layer between the first contact feature and the second contact feature;
an interfacial layer disposed between the electrode and the first doped region; and
a high-k dielectric layer dispose between the interfacial layer and the electrode.

10. The device structure of claim 9, wherein the electrode comprises titanium nitride or polysilicon.

11. The device structure of claim 9, wherein the interfacial layer comprises silicon oxynitride.

12. The device structure of claim 9, wherein the high-k dielectric layer comprises hafnium oxide.

13. The device structure of claim 9, wherein each of the first contact feature and the second contact feature interfaces the first doped region by way of a silicide feature.

14. The device structure of claim 12, further comprising a spacer layer disposed along sidewalls of the electrode, the interfacial layer, and the high-k dielectric layer.

15. A method, comprising:
performing an ion implantation process to a substrate to form a doped region;
forming over the substrate a stack that includes a plurality of channel layers interleaved by a plurality of sacrificial layers;
patterning the stack and the substrate to form a fin-shaped structure having a base portion formed from the substrate and a stack portion formed from the stack;
forming an isolation feature around the base portion;
forming a dummy gate stack over a channel region of the fin-shaped structure;
depositing a gate spacer layer over the dummy gate stack;
after the depositing of the gate spacer layer, recessing a source/drain region of the fin-shaped structure to form a source/drain trench extending into the base portion;
selectively removing the plurality of sacrificial layers in the channel region to release the plurality of channel layers as a plurality of channel members;
depositing a dummy layer over the plurality of channel members;
selectively and partially recessing the dummy layer to form inner spacer recesses among the plurality of channel members and a bottom dummy feature over a bottom surface of the source/drain trench;
forming inner spacer features in the inner spacer recesses;
forming a source/drain feature over the source/drain region;
after the forming of the source/drain feature, removing the dummy gate stack;
removing the dummy layer;
forming a gate structure to wrap around each of the plurality of channel members;
forming a frontside interconnect structure over the gate structure; and
after the forming of the frontside interconnect structure, forming a backside device over the doped region.

16. The method of claim 15, wherein the forming of the backside device comprises:
bonding a carrier substrate to the frontside interconnect structure;
after the bonding, flipping the substrate upside down;
forming an electrode over the doped region;
depositing a backside dielectric layer over the doped region and the electrode; and
forming a first contact feature and a second contact feature through the backside dielectric layer to interface the doped region,
wherein the electrode is disposed between the first contact feature and the second contact feature.

17. The method of claim 16, wherein the forming of the first contact feature and the second contact feature comprises:
forming a first contact opening and a second contact opening through the backside dielectric layer to expose the doped region;
forming a first silicide feature in the first contact opening and a second silicide feature in the second contact opening; and
depositing a metal fill layer over the first silicide feature and the second silicide feature.

18. The method of claim 16, further comprising:
before the forming of the electrode over the doped region, depositing an interfacial layer over the doped region,
wherein, after the forming of the electrode, the interfacial layer is disposed between the doped region and the electrode.

19. The method of claim 18, further comprising:
before the forming of the electrode over the doped region, depositing a high-k dielectric layer over the interfacial layer over the doped region,
wherein, after the forming of the electrode, the interfacial layer and the high-k dielectric layer is disposed between the doped region and the electrode.

20. The method of claim 15, wherein the backside device comprises a diode, a bipolar junction transistor, a resistor, a capacitor, a metal oxide semiconductor transistor, or an embedded dynamic random access memory (eDRAM).
